(19) United States
(12) Patent Application Publication
(10) Pub. No.: US 2025/0159865 A1
(43) Pub. Date: May 15, 2025

(54) SELF-ALIGNED CAPACITORS FOR THREE-DIMENSIONAL MEMORY SYSTEMS

(71) Applicant: Micron Technology, Inc., Boise, ID (US)

(72) Inventors: Yuanzhi Ma, Boise, ID (US); Scott E. Sills, Boise, ID (US); Si-Woo Lee, Boise, ID (US)

(21) Appl. No.: 18/933,964

(22) Filed: Oct. 31, 2024

Related U.S. Application Data
(60) Provisional application No. 63/548,330, filed on Nov. 13, 2023.

(51) Int. Cl. H10B 12/00; H10B 53/20; H10B 53/30

(52) U.S. Cl. CPC H10B 12/30; H10B 12/03; H10B 12/05; H10B 53/20; H10B 53/30

(57) ABSTRACT

Methods, systems, and devices for self-aligned capacitors for three-dimensional memory systems are described. For example, a capacitor of a memory cell may include multiple interfaces (e.g., concentric interfaces, dielectric interfaces, interfaces at different relative radial positions from an axis of the capacitor) between material portions of a first electrode and a second electrode, each across a respective portion of a dielectric material. A separating dielectric feature may be included between the capacitor and a cell selection transistor of the memory cell, which may support self-alignment of features of the capacitor with features of the cell selection transistor (e.g., self-alignment for fabrication operations associated with forming the capacitor).

### CROSS REFERENCE

The present Application for Patent claims priority to U.S. Patent Application No. 63/548,330 by Ma et al., entitled “SELF-ALIGNED CAPACITORS FOR THREE-DIMENSIONAL MEMORY SYSTEMS,” filed Nov. 13, 2023, which is assigned to the assignee hereof, and which is expressly incorporated by reference in its entirety herein.

### TECHNICAL FIELD

The following relates to one or more systems for memory, including self-aligned capacitors for three-dimensional memory systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells in a non-volatile configuration may maintain stored logic states for extended periods of time even in the absence of an external power source. Memory cells in a volatile configuration may lose stored states when disconnected from an external power source.

### BRIEF DESCRIPTION OF THE DRAWINGS

FIG. 1 shows an example of a memory device that supports self-aligned capacitors for three-dimensional memory systems in accordance with examples as disclosed herein.

FIG. 2 shows an example of an array architecture that supports self-aligned capacitors for three-dimensional memory systems in accordance with examples as disclosed herein.

FIGS. 3 through 38 show examples of fabrication operations that support self-aligned capacitors for three-dimensional memory systems in accordance with examples as disclosed herein.

FIG. 39 shows a flowchart illustrating a method or methods that support self-aligned capacitors for three-dimensional memory systems in accordance with examples as disclosed herein.

### DETAILED DESCRIPTION

Some memory devices may include one or more three-dimensional arrays of memory cells formed over a substrate. For example, a memory device may include multiple levels of memory cells, where a level may refer to a dimension above the substrate (e.g., a level extending along one or more horizontal directions above a substrate). In some implementations, a memory cell may include a capacitor operable to store a charge indicative of logic state and a switching component (e.g., a cell selection component, a transistor) operable to couple the capacitor with an access line such that the logic state may be written to, or read from, or both from the capacitor, among other operations. Three-dimensional arrays of memory cells may support reduced physical size of memory cells, a reduced area (e.g., of a substrate) or both, and thus an increased array density or a reduced footprint, among other benefits. However, some techniques for forming three-dimensional arrays of memory cells may result in variations between capacitors and corresponding switching components (e.g., interface variations, contact junction variations), which may result in variations in cell capacitance or other memory cell electrical characteristics, or variable memory cell dimensions, or both, which may be accompanied by decreased device performance, device yield, or both.

In accordance with the examples described herein, a manufacturing process for a memory device may support memory cells (e.g., stud cells) being formed with self-aligned features that reduce distance and distance variability between memory cell capacitors and associated switching components. For example, a capacitor of a memory cell may include multiple portions (e.g., layers) of dielectric material between portions, such as concentric portions, of a first electrode (e.g., a bottom plate) and a second electrode (e.g., a top plate). The first electrode may include a first portion that wraps around or is otherwise coupled with a portion of a semiconductor material that is contiguous with a channel of a transistor (e.g., a cell selection transistor), and the second electrode may include at least a portion that wraps around the first portion of the first electrode (e.g., separated by a first portion of the dielectric material between the first portion of the first electrode and the portion of the second electrode). The first electrode may also include at least a second portion that wraps around the portion of the second electrode (e.g., separated by a second portion of the dielectric material between the portion of the second electrode and the second portion of the first electrode). The memory device may also include a second dielectric between the cell selection transistor and the capacitor (e.g., along a horizontal direction above a substrate) and around the semiconductor material, which may support a self-alignment of the capacitor (e.g., self-alignment for formation operations). Thus, the capacitor may include multiple interfaces (e.g., concentric interfaces, interfaces at different relative radial positions from an axis of the capacitor) between material portions of the first electrode and the second electrode, each across a respective portion of the dielectric material, and a separating dielectric feature may be included between the capacitor and the cell selection transistor of a memory cell that supports self-alignment of features of the capacitor with features of the cell selection transistor (e.g., as a self-aligned cell contact junction). Such techniques may support a relatively dense array architecture, including for three-dimensional arrays of memory cells, which may support relatively high storage capacity, relatively low fabrication cost, or relatively low operational latency, among other benefits.

In addition to applicability in memory systems as described herein, techniques for manufacturing self-aligned capacitors for three-dimensional memory systems may be generally implemented to improve the performance (including gaming, among other applications) of various electronic devices and systems. Some electronic device applications, including gaming and other high-performance applications, may be associated with relatively high processing characteristics while also benefitting from relatively quick response times to improve user experience. As such, increasing processing speed, decreasing response times, or otherwise improving the performance electronic devices may be desirable. Implementing the techniques described herein may improve the performance of electronic devices by increasing the capacitance of three-dimensional arrays of volatile memory cells (e.g., DRAM cells, FeRAM cells), supporting more-uniform electrical characteristics, and increasing array density, which may increase semiconductor fabrication yield, improve memory access speeds, decrease processing times, decrease latency times, improve response times, or otherwise improve user experience, among other benefits.

Features of the disclosure are illustrated and described in the context of memory devices and related circuitry. Features of the disclosure are further illustrated and described in the context of material arrangements of a set of fabrication operations and an example flowchart.

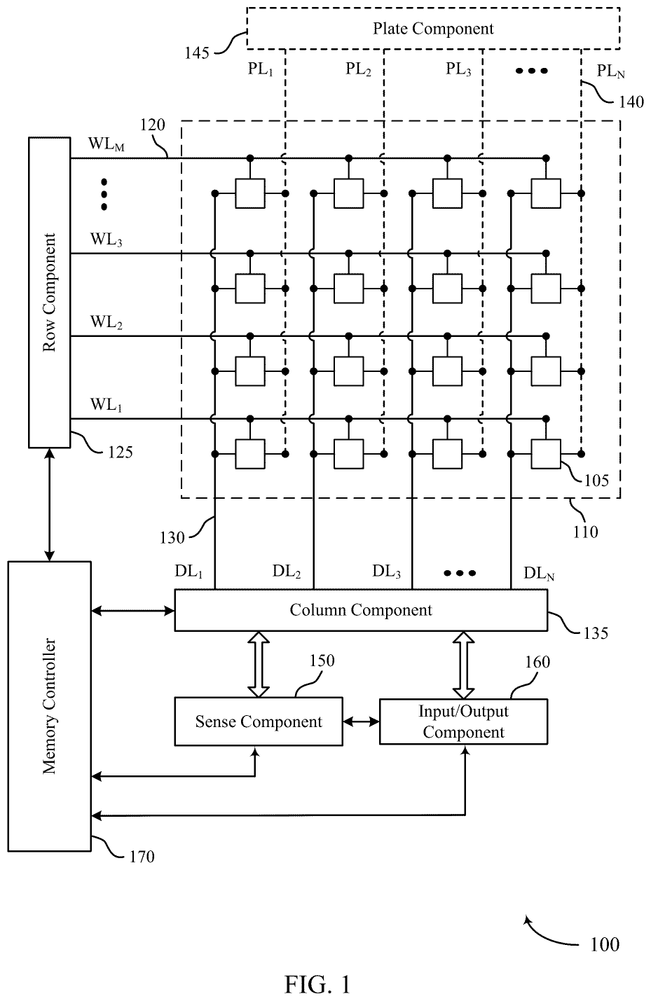

FIG. 1 shows an example of a memory device 100 that supports self-aligned capacitors for three-dimensional memory systems in accordance with examples as disclosed herein. The memory device 100 may be referred to as or included in a memory die or an electronic memory apparatus. The memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array 110 (e.g., a memory array) of the memory device 100 where, in some examples, an array 110 may refer to a contiguous set of memory cells 105 (e.g., a contiguous set of elements of a semiconductor chip).

In some examples, a memory cell 105 may store an electric charge representative of the programmable logic states in a storage component (e.g., a capacitor, a capacitive memory element, a capacitive storage element). In some examples, a charged and uncharged capacitor may represent two logic states, respectively. In some other examples, a positively charged (e.g., a first polarity, a positive polarity) and negatively charged (e.g., a second polarity, a negative polarity) capacitor may represent two logic states, respectively. DRAM or FeRAM architectures may use such designs, and the capacitor employed may include a dielectric material with linear or para-electric polarization properties as an insulator. In some examples, different levels of charge of a capacitor may represent different logic states, which, in some examples, may support more than two logic states in a respective memory cell 105. In some examples, such as FeRAM architectures, a memory cell 105 may include a ferroelectric capacitor having a ferroelectric material as an insulating (e.g., non-conductive) layer between terminals of the capacitor. Different levels or polarities of polarization of a ferroelectric capacitor may represent different logic states (e.g., supporting two or more logic states in a respective memory cell 105).

In the example of memory device 100, each row of memory cells 105 may be coupled with one or more word lines 120 (e.g., WL₁ through WL_{M}), and each column of memory cells 105 may be coupled with one or more digit lines 130 (e.g., DL₁ through DL_{N}). Each of the word lines 120 and digit lines 130 may be an example of an access line of the memory device 100. In general, one memory cell 105 may be located at the intersection of (e.g., coupled with, coupled between) a word line 120 and a digit line 130. This intersection may be referred to as an address of a memory cell 105. A target (e.g., selected) memory cell 105 may be a memory cell 105 located at the intersection of an activated or otherwise selected word line 120 and an activated or otherwise selected digit line 130.

In some architectures, a storage component of a memory cell 105 may be electrically isolated from a digit line 130 by a cell selection component, which, in some examples, may be referred to as a switching component or a selector device of or otherwise associated with the memory cell 105. A word line 120 may be coupled with the cell selection component (e.g., via a control node of the cell selection component) and may control the cell selection component of the memory cell 105. For example, the cell selection component may be a transistor and the word line 120 may be coupled with or be a portion of a gate of the transistor (e.g., where a gate node of the transistor may be a control node of the transistor). Activating a word line 120 may result in an electrical connection (e.g., a closed circuit) between a respective storage component of one or more memory cells 105 (e.g., a row of memory cells 105) and one or more corresponding digit lines 130, which may be referred to as activating the one or more memory cells 105 or coupling the one or more memory cells 105 with a respective one or more digit lines 130. A digit line 130 may then be accessed to write to or read from the respective memory cell 105.

In some examples, memory cells 105 may also be coupled with one or more plate lines 140 (e.g., PL₁ through PL_{N}). In some examples, each of the plate lines 140 may be independently addressable (e.g., supporting individual selection or biasing). In some examples, the plurality of plate lines 140 may represent or be otherwise functionally equivalent with a common plate, or other common node (e.g., a plate node common to each of the memory cells 105 of the array 110). For implementations in which a memory cell 105 employs a capacitor for storing a logic state, a digit line 130 may provide access to a first terminal (e.g., a first plate) of the capacitor, and a plate line 140 may provide access to or be at least a portion of a second terminal (e.g., a second plate) of the capacitor. Although the plurality of plate lines 140 of the memory device 100 are shown as being parallel with the plurality of digit lines 130, in some other examples, a plurality of plate lines 140 may be parallel with the plurality of word lines 120, or in any other configuration (e.g., a common planar conductor, a common plate layer, a common plate node).

Access operations such as reading, writing, rewriting, and refreshing may be performed on a memory cell 105 by activating (e.g., selecting) a word line 120, a digit line 130, or a plate line 140 coupled with the memory cell 105, which may include applying a voltage, a charge, or a current to the respective access line. After selecting a memory cell 105 (e.g., in a read operation), a resulting signal may be used to determine the logic state stored by the memory cell 105. For example, a memory cell 105 with a capacitive memory element storing a logic state may be selected, and the resulting flow of charge via an access line or resulting voltage of an access line may be detected to determine the programmed logic state stored by the memory cell 105.

Accessing memory cells 105 may be controlled using a row component 125 (e.g., a row decoder), a column component 135 (e.g., a column decoder), or a plate component 145 (e.g., a plate decoder), or a combination thereof. For example, a row component 125 may receive a row address from the memory controller 170 and activate a corresponding word line 120 based on the received row address. Similarly, a column component 135 may receive a column address from the memory controller 170 and activate a corresponding digit line 130. In some examples, such access operations may be accompanied by a plate component 145 biasing one or more of the plate lines 140 (e.g., biasing one of the plate lines 140, biasing some or all the plate lines 140, biasing a common plate).

In some examples, the memory controller 170 may control operations (e.g., read operations, write operations, rewrite operations, refresh operations) of memory cells 105 using one or more components (e.g., row component 125, column component 135, plate component 145, sense component 150). In some cases, one or more of the row component 125, the column component 135, the plate component 145, and the sense component 150 may be co-located with or otherwise included as part of the memory controller 170. The memory controller 170 may generate row and column address signals to activate a desired word line 120 and digit line 130. The memory controller 170 may also generate or control various voltages or currents used during the operation of memory device 100.

A memory cell 105 may be written (e.g., programmed, set) by activating the relevant word line 120, digit line 130, or plate line 140 (e.g., via a memory controller 170). In other words, a logic state may be stored in a memory cell 105. A row component 125, column component 135, or plate component 145 may accept data, for example, via input/output component 160, to be written to the memory cells 105. In some examples, a write operation may be performed at least in part by a sense component 150, or a write operation may be configured to bypass a sense component 150.

In the case of a capacitive memory element, a memory cell 105 may be written by applying a voltage to (e.g., across) a capacitor, and then isolating the capacitor (e.g., isolating the capacitor from a voltage source used to write the memory cell 105, floating the capacitor) to store a charge in the capacitor associated with a desired logic state. In the case of ferroelectric memory, a ferroelectric memory element (e.g., a ferroelectric capacitor) of a memory cell 105 may be written by applying a voltage with a magnitude high enough to polarize the ferroelectric memory element (e.g., applying a saturation voltage) with a polarization associated with a desired logic state, and the ferroelectric memory element may be isolated (e.g., floating), or a zero net voltage may be applied across the ferroelectric memory element (e.g., grounding, virtually grounding, or equalizing a voltage across the ferroelectric memory element).

A memory cell 105 may be read (e.g., sensed) by a sense component 150 when the memory cell 105 is accessed (e.g., in cooperation with the memory controller 170) to determine a logic state stored by (e.g., written to) the memory cell 105. For example, the sense component 150 may be configured to evaluate a current or charge transfer through or from the memory cell 105, or a voltage resulting from coupling the memory cell 105 with the sense component 150, responsive to a read operation. The sense component 150 may provide an output signal indicative of the logic state read from the memory cell 105 to one or more components (e.g., to the column component 135, the input/output component 160, to the memory controller 170).

A sense component 150 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 150 may include a collection of circuit elements that are repeated for each of a set or subset of digit lines 130 coupled with the sense component 150. For example, a sense component 150 may include a separate sensing circuit (e.g., a separate or duplicated sense amplifier, a separate or duplicated signal development component) for each of a set of digit lines 130 coupled with the sense component 150, such that a logic state may be separately detected for a respective memory cell 105 coupled with a respective one of the set of digit lines 130.

In some implementations, the memory device 100 may include one or more three-dimensional arrays of memory cells 105 formed over a substrate. For example, one or more arrays 110 may be formed above a substrate with word lines 120 arranged at different levels along a direction from a substrate and digit lines 130 arranged at different positions along a direction above the substrate (e.g., with each digit line 130 extending along the direction from the substrate and each word line 120 extending along the direction above the substrate). Additionally, or alternatively, one or more arrays 110 may be formed above a substrate with digit lines 130 arranged at different levels along a direction from a substrate and word lines 120 arranged at different positions along a direction above the substrate. Reducing the physical size of memory cells 105 may support increased density of such arrays 110, and thus an increased storage capacity for a given size of the arrays 110, among other benefits. However, reducing the physical size of memory cells 105 may include reducing one or more dimensions of capacitors of the memory cells 105 which, for some capacitor architectures, may reduce a capacity of the memory cells 105 to store a charge that corresponds to a given logic state. The reduced capacity to store charge may be associated with relatively small read margins, relatively high refresh rates, or relatively complex access circuitry, among other accompanying characteristics of the memory device 100.

In accordance with the examples described herein, a manufacturing process for a memory device 100 may support memory cells 105 (e.g., stud cells) being formed with self-aligned features that reduce distance and distance variability between memory cell capacitors and associated cell selection transistors. For example, respective capacitors of the memory cells 105 may each include multiple portions (e.g., layers) of a dielectric between portions, such as concentric portions, of a first electrode (e.g., a bottom plate) and a second electrode (e.g., a top plate). The memory cells 105 may also include a dielectric between the cell selection transistors and the capacitors (e.g., along a horizontal direction above a substrate), which may support self-alignment of features of the capacitor with features of the cell selection transistor (e.g., as a self-aligned cell contact junction). Such techniques may support a relatively dense array architecture, including for three-dimensional arrays of memory cells 105, which may support relatively high storage capacity, relatively low fabrication cost, or relatively low operational latency, among other benefits.

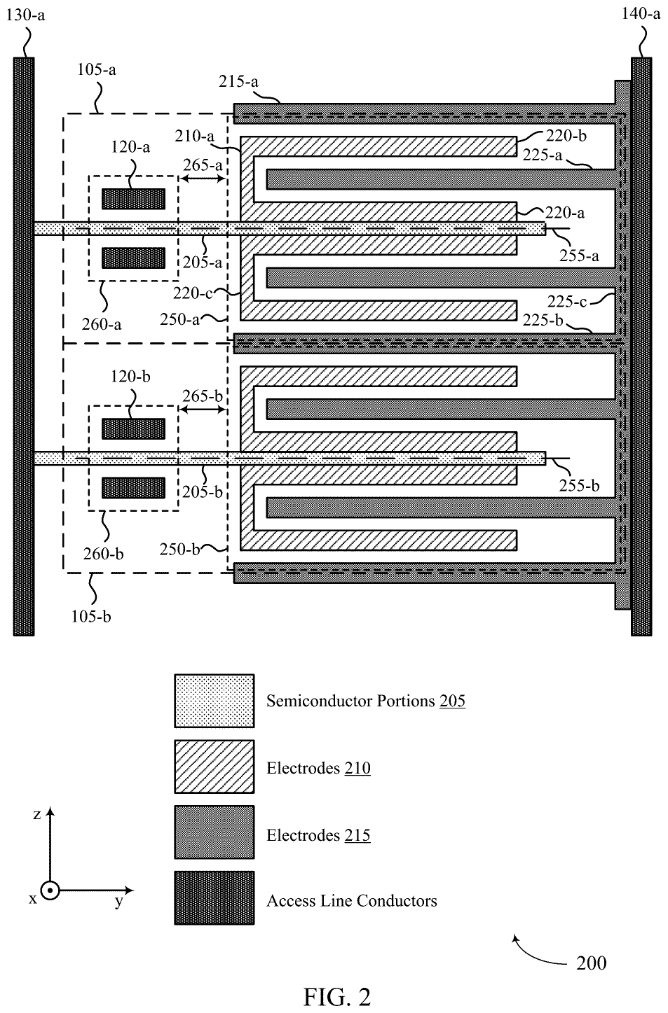

FIG. 2 shows an example of an array architecture 200 that supports self-aligned capacitors for three-dimensional memory systems in accordance with examples as disclosed herein. The array architecture 200 may illustrate an example for implementing aspects of an array 110 in a memory device 100, which may include features formed above a substrate (not shown), such as features formed above a crystalline semiconductor wafer. For example, the array architecture 200 may illustrate an architecture of memory cells 105, which may be implemented in a three-dimensional array 110. Aspects of the array architecture 200 may be described with reference to an x-direction, a y-direction, and a z-direction, with the example of FIG. 2 providing an illustrative cross-sectional view of features of the array architecture 200 in a yz-plane. In some implementations, the x-direction may be a direction over (e.g., parallel to, above) the substrate, the y-direction may be another direction over (e.g., parallel to, above) the substrate, and the z-direction may be a direction away from the substrate (e.g., perpendicular to or otherwise away from a surface of the substrate, a height direction, a thickness direction). In some other implementations, the x-direction may be a direction away from a substrate, the y-direction may be a direction over the substrate, and the z-direction may be another direction over the substrate. Aspects of the array architecture 200 may be repeated in various quantities and arrangements along the x-direction, the y-direction, and the z-direction to support various three-dimensional configurations of memory cells 105.

In the example of array architecture 200, each memory cell 105 includes a respective capacitor 250 and a respective transistor 260 (e.g., a cell selection transistor). Each memory cell 105 (e.g., of a column of memory cells 105 along the z-direction) may also be associated with a digit line 130 (e.g., digit line 130-a associated with memory cells 105-a and 105-b, extending along the z-direction) and a respective word line 120 (e.g., word line 120-a associated with memory cell 105-a, word line 120-b associated with memory cell 105-b, each extending along the x-direction). The word lines 120 may act as a gate of or be otherwise coupled with a gate of the transistors 260, and biasing a word line 120 (e.g., with an activation bias, with a selection bias) may be operable to couple the capacitor 250 of a memory cell 105 with a digit line 130 (e.g., based on activating a semiconductor channel of the respective transistor 260). The array architecture 200 also includes a plate line 140-a coupled with the capacitors 250 and extending along at least the z-direction. In some examples, the plate line 140-a may be associated with a column of memory cells 105 that include the memory cells 105-a and 105-b. In some examples, the plate line 140-a may also extend along the x-direction, which may include being coupled with additional memory cells 105 along the x-direction (e.g., as a common plate for multiple columns of memory cells 105 arranged along the x-direction.

Each of the memory cells 105 may be associated with a respective semiconductor portion 205 (e.g., a semiconductor portion 205-a associated with memory cell 105-a, a semiconductor portion 205-b associated with memory cell 105-b) that extends along the y-direction (e.g., from the digit line 130-a). At least a portion of the semiconductor portion 205 associated with a memory cell 105 may support a channel of the transistor 260 associated with the memory cell 105. For example, the word line 120-a, operating as a gate of the transistor 260-a, may be operable to modulate a conductivity of a channel portion of the semiconductor portion 205-a. In some examples, word lines 120 may be associated with one or more conductors that extend along the x-direction adjacent to the semiconductor portions 205 (e.g., in a pass-by gate configuration). In some examples, the word lines 120 may be associated with conductor portions that wrap around the semiconductor portions 205 (e.g., in an all-around gate configuration, where semiconductor portions 205 extend through openings in a conductive material of the word lines 120).

The semiconductor portions 205 may include various semiconductor materials, such as silicon (e.g., crystalline silicon, epitaxial silicon, polysilicon), and portions of the semiconductor portions 205 associated with the transistors 260 may be doped to support the channel characteristics of the transistors 260. For example, to support an n-type transistor configuration for the transistors 260, the semiconductor portions 205 may include n-type doping, or a portion with p-type doping between portions with n-type doping (e.g., along the y-direction), among other doping configurations. The semiconductor portions 205 may be formed with various cross-sectional shapes (e.g., in an xz-plane), such as with a circular cross-section, an oval cross-section, a square cross-section, a rectangular cross-section, a polygonal cross-section, and others. In some examples, the semiconductor portions 205 may referred to as a stud of a capacitor 250 or of a memory cell 105.

Each capacitor 250 may be associated with an electrode 210 (e.g., a bottom electrode) coupled with a transistor 260, an electrode 215 (e.g., a top electrode) coupled with the plate line 140-a, and a dielectric material (not shown) between the electrode 210 and the electrode 215. For example, the capacitor 250-a may be associated with an electrode 210-a and an electrode 215-a, and so on. In some examples, two or more electrodes 215 of adjacent capacitors 250 may be electrically coupled (e.g., in a common plate configuration). In various examples, the electrodes 215 may be formed with a same material (e.g., a contiguous material) as the plate line 140-a, or may be formed with a different material than the plate line 140-a, or may be otherwise electrically coupled with the plate line 140-a. In some examples of the described techniques (e.g., in a three-sided stud cell, at least a portion of (e.g., an outer portion of) an electrode 215 may be shared between capacitors 250 of adjacent memory cells 105 in an array 110, which may provide a shielding effect between electrodes 210 of adjacent memory cells 105, which may reduce disturbance effects between the adjacent memory cells 105. In some examples, at least a portion of electrodes 210 may be formed in contact with (e.g., around an end of, in contact with an end of) respective semiconductor portions 205 or may be otherwise coupled with a channel of a respective transistor 260. The electrodes 210 and electrodes 215 may be formed from various materials such as titanium nitride or other conductive materials, and electrodes 215 may be formed with a same material as electrodes 210 or with a different material than electrodes 210.

The electrodes 210 and electrodes 215 may include various material portions that are formed around (e.g., in a concentric manner) a respective axis 255, such as an axis 255-a of the memory cell 105-a and an axis 255-b of the memory cell 105-b (e.g., axes along the y-direction, axes through respective semiconductor portions 205-a, axes along a direction of a channel of a transistor 260-a and a transistor 260-b), where such portions may be formed around an end of a respective semiconductor portion 205 (e.g., an end along the y-direction). For example, the electrode 210-a may include a portion 220-a, which may be in contact with and wrap around the semiconductor portion 205-a, and a portion 220-b, which may wrap around the portion 220-a. In some examples, the portion 220-a and the portion 220-b may be formed with a contiguous material, which may include a portion 220-c that extends at least in part along one or more radial directions (e.g., directions radial to the axis 255-a) between the portion 220-a and the portion 220-b. Accordingly, an electrode 210 may be configured in a toroidal shape (e.g., a cupped shape) having a cavity (e.g., a depression, a well) on an end of the electrode 210 between a portion 220 and a portion 220, as illustrated in FIG. 2. Although the portion 220-a is illustrated as being non-contiguous over the semiconductor portion 205-a (e.g., the semiconductor portion 205-a extending through the portion 220-a), in some other examples, a portion 220 may be contiguous over (e.g., may cover) an end of a semiconductor portion 205.

The electrode 215-a may include a portion 225-a and a portion 225-b. The portion 225-a may be arranged between the portion 220-a and the portion 220-b, and may wrap around the portion 220-a. In some examples, the portion 225-a may be contiguous over (e.g., may cover) an end of the portion 220-a, an end of the portion of the semiconductor portion 205-a, or both. The electrode 215-a may wrap around the portion 220-b, such that the portion 220-b is positioned between the portion 225-a and the portion 225-b. In some examples, the portion 225-a and the portion 225-b may be formed with a contiguous material, which may include a portion 225-c that extends at least in part along one or more radial directions (e.g., directions radial to the axis 255-a) between the portion 225-a and the portion 225-b. In some cases, the portion 225-b may have a greater extent (e.g., along the negative y-direction) than the portion 225-a. For example, the portion 225-b may extend to or beyond an end of the electrode 210, as illustrated in FIG. 2. Such an extension may enhance an ability of the portion 225-b to act as a barrier (e.g., a shield) between adjacent memory cells 105 (e.g., between adjacent electrodes 210), which may mitigate disturbance effects between adjacent memory cells 105 (e.g., disturbances associated with access operations on one or both of adjacent memory cells 105). In some other examples of the described techniques (e.g., in a two-sided stud cell configuration), such features (e.g., a portion of bottom electrodes 215 shared between memory cells 105, portion 225-b) may be omitted.

A dielectric material between an electrode 210 and an electrode 215 may support a capacitance between the electrode 210 and the electrode 215, with which a charge indicative of a logic state may be stored in a memory cell 105. In some examples, such a dielectric material may include one or more materials that support a linear capacitance (e.g., for operating memory cells 105 in accordance with a DRAM architecture). In some examples, such a dielectric material may include one or more materials that support a ferroelectric capacitance (e.g., a polarization, for operating memory cells 105 in accordance with an FeRAM architecture).

A dielectric material may contiguously extend between portions 220 of the electrode 210 and portions 225 of the electrode 215. For example, for the capacitor 250-a, a dielectric material may include a first portion arranged between the portion 220-a and the portion 225-a that may wrap around the portion 220-a, an end of the semiconductor portion 205, or both, a second portion arranged between the portion 225-a and the portion 220-b that may wrap around the portion 225-a, and a third portion arranged between the portion 220-b and the portion 225-b that may wrap around the portion 220-b. In some cases, the dielectric material may be contiguous between the portions (e.g., with one or more portions that extend along one or more directions radial to the axis 255-a). For example, the first portion of the dielectric material may be contiguous with the second portion over an end of portion 225-a, and the second portion may be contiguous with the third portion over an end of the portions 220-b. In such cases, the portion 220-a may be contiguous with the portion 220-b over an end of the first portion and the second portion, and the portion 225-a may be contiguous with the portion 225-b over an end of the second portion, an end of the portion 220-b, and an end of the third portion. For cases in which the dielectric material is implemented with three concentric interfaces between an electrode 210 and an electrode 215 for each capacitor 250 (e.g., interfaces at different positions or layers radially from a respective axis 255), the capacitors 250 may be referred to as three-sided stud capacitors, which may provide a relatively large capacitance (e.g., compared with two-sided stud capacitors) in a relatively small volume.

In accordance with examples disclosed herein, techniques for forming the array architecture 200 may support self-alignment of features of capacitors 250, which may support reducing respective distances 265 between capacitors 250 and corresponding transistors 260, or variability among distances 265 of the array architecture (e.g., between different instances of distances 265 along the z-direction, between different instances of distances 265 along the x-direction, or both). For example, such techniques may include forming a second dielectric material (e.g., a layer of a second dielectric, different than one or more dielectrics of transistors 260, capacitors 250, or both), such as silicon oxycarbide, between transistors 260 and electrodes 210, which may provide for self-alignment of the capacitor 250 (e.g., self-alignment for formation of one or more portions of the electrode 210, a material boundary for differential processing, such as preferential material removal). In some cases, first portions of electrodes 210 (e.g., portions 220-a) may be contiguous with second portions of the electrodes 210 (e.g., portions 220-b) via third portions of the electrodes 210 (e.g., portions 220-c) that are in contact with the second dielectric material. Additionally, or alternatively, portions of the first dielectric material (e.g., a dielectric of capacitors 250 between electrodes 210 and electrodes 215) may be in contact with the second dielectric material (e.g., between portions 220-b of the electrodes 210 and portions 225-b of the electrodes 215).

In some cases, the second dielectric material may extend to the transistor 260 and may contact or may be contiguous with a dielectric material of the transistor 260, such as a gate dielectric (e.g., a gate oxide, a dielectric between word lines 120 and semiconductor portions 205). In some such examples, an interface between the second dielectric material and a gate dielectric may include a grain boundary (e.g., a crystal grain boundary, a material boundary, a boundary indicative of different processing steps). Additionally, or alternatively, the array architecture 200 may include a third dielectric material between the second dielectric material and the transistors 260. In such cases, the third dielectric material may be a different material than the second dielectric material, such as a nitride material.

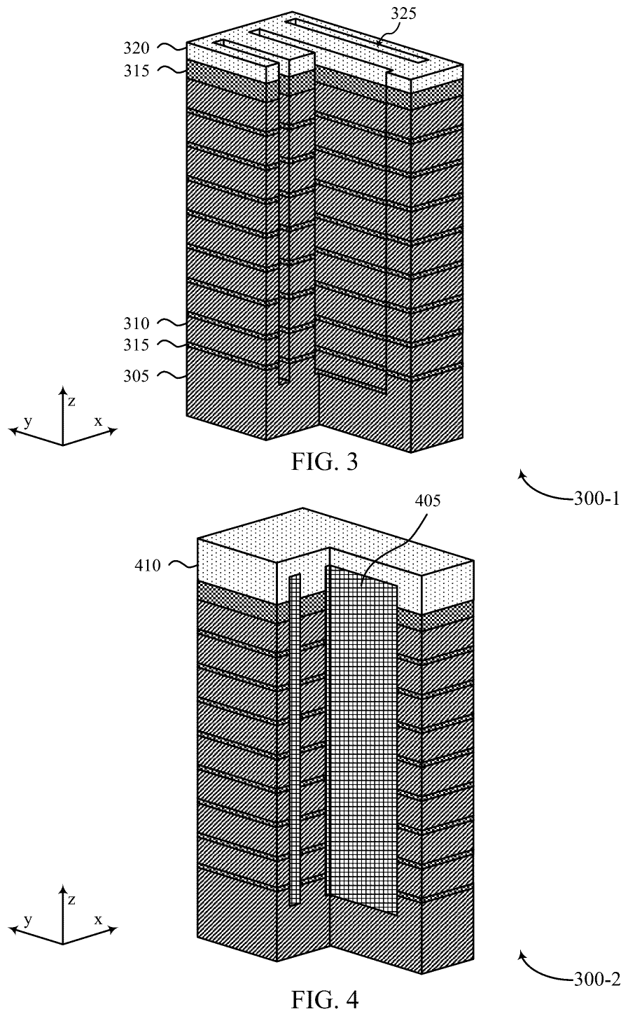

FIGS. 3 through 38 illustrate examples of fabrication operations that support self-aligned capacitors for three-dimensional memory systems in accordance with examples as disclosed herein. For example, FIGS. 3 through 38 may illustrate a sequence of operations for fabricating aspects of a material arrangement 300, which may be a portion of a memory device (e.g., a portion of a memory device 100, a portion of a memory die), and may include aspects of the array architecture 200. Each of FIGS. 3 through 38 may illustrate aspects of the material arrangement 300 after different subsets of the fabrication operations for forming the material arrangement 300 (e.g., illustrated as a material arrangement 300-1 after a first set of one or more fabrication operations, as a material arrangement 300-2 after a second set of one or more fabrication operations, and so on). Each view of FIGS. 3 through 38 may be described with reference to an x-direction, a y-direction, and a z-direction, as illustrated, which may correspond to the respective directions described with reference to the array architecture 200. Aspects of the material arrangement 300 may be illustrated in accordance with cut planes (e.g., along xz-planes, along yz-planes) to show various embedded features of the material arrangement 300.

Operations illustrated in and described with reference to FIGS. 3 through 38 may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the material arrangement 300. In some examples, operations performed by such a manufacturing system may be supported by a process controller or its components as described herein (e.g., including instructions stored in a non-transitory computer-readable medium that are executable by a processing system to cause the manufacturing system to perform the operations).

Although aspects of the material arrangement 300 illustrate examples of relative dimensions and quantities of various features, aspects of the material arrangement 300 may be implemented with other relative dimensions or quantities of such features in accordance with examples as disclosed herein. Moreover, aspects of the material arrangement 300 may be repeated in various manners (e.g., along the x-direction, along the y-direction, along the z-direction) to support a three-dimensional architecture of memory cells 105. In the following description of the material arrangement 300, some methods, techniques, processes, and operations may be performed in different orders, or at different times, or otherwise modified. Further, some operations for fabricating a material arrangement 300 (e.g., for fabrication in accordance with an array architecture 200) may be omitted from the described fabrication operations, or other operations may be added to the described fabrication operations.

FIG. 3 illustrates the material arrangement 300 (e.g., as a material arrangement 300-1) after a first set of one or more fabrication operations. The first set of operations may include forming alternating layers of a semiconductor material 310 and a material 315 over a substrate 305. Layers of the semiconductor material 310 and the material 315 may each extend over a substrate 305 (e.g., in respective xy-planes). In some examples, the substrate 305 may be a semiconductor substrate, such as a semiconductor wafer (e.g., a wafer of crystalline silicon), from which one or more dies may be formed (e.g., separated, diced). In some examples, a quantity of layers of the semiconductor material 310 may correspond to a quantity of levels (e.g., layers, decks) of memory cells 105 along the z-direction that are implemented with the material arrangement 300.

In some examples, forming the semiconductor material 310, the material 315, or both may implement epitaxial formation techniques (e.g., epitaxial deposition). For example, the substrate 305 may have a crystalline atomic arrangement, and the crystalline arrangement of the substrate 305 may be translated through (e.g., contiguous through) alternating portions (e.g., layers, levels) of the material 315 and the semiconductor material 310. To support such techniques, the material 315 and the semiconductor material 310 may be selected to support translation of the crystalline arrangement from the substrate 305 as the alternating layers of the material 315 and the semiconductor material 310 are formed (e.g., deposited) along the z-direction (e.g., across boundaries between and through the substrate 305, the material 315, and the semiconductor material 310). In some examples, the semiconductor material 310 may be the same semiconductor material as the substrate 305 (e.g., silicon or other semiconductor), and the material 315 may be a compound of the semiconductor material or another material that is otherwise compatible for translating the atomic arrangement of the substrate 305. For example, the semiconductor material 310 may be silicon (e.g., epitaxial silicon) and the material 315 may be silicon germanium (e.g., epitaxial silicon germanium). In some examples, the semiconductor material 310 and the material 315 may also be selected to support differential processing techniques, such as selecting the material 315 to support being preferentially removed while maintaining portions of the semiconductor material 310, the substrate 305, or both.

In some examples, the first set of operations may include forming a covering (e.g., a cap) of the material 315, as depicted in FIG. 3, which may have a greater thickness along the z-direction than other layers of the material 315. In some other examples, the first set of operations may omit forming a covering of the material 315. The first set of operations may also include forming a material 320 (e.g., a hard mask), such as an oxide material, over the alternating layers of the semiconductor material 310 and the material 315. In some examples, the first set of operations may include forming (e.g., etching) one or more trenches 325 in the alternating layers of the semiconductor material 310 and the material 315, which may implement a material removal operation that is relatively directional along the z-direction, such as a dry etch operation (e.g., using a patterned mask, not shown). In some examples, forming the trenches 325 may form (e.g., divide) portions of the semiconductor material 310 into semiconductor portions 205, or otherwise support formation of semiconductor portions 205 (e.g., based on further material removal operations).

FIG. 4 illustrates the material arrangement 300 (e.g., as a material arrangement 300-2) after a second set of one or more fabrication operations. The second set of operations may include forming a material 405 within the one or more trenches 325. In some examples, the material 405 may be carbon or another sacrificial material. As a sacrificial material, the material 405 may be selected for having relatively benign removal characteristics, such that it may be removed relatively easily in later operations (e.g., with relatively limited effect on other remaining materials of the material arrangement 300). The material 405 also may be selected to have relatively favorable differential processing characteristics relative to neighboring (e.g., contacting) materials. In some examples, the second set of operations may also include a planarization operation (e.g., a chemical-mechanical polishing (CMP) operation) to planarize the material 405, the material 320 (e.g., the covering portion of the material 320), or both. In some examples, the second set of operations may also include forming a material 410 over the material arrangement 300 (e.g., an oxide material, a hard mask material, which may be the same material as the material 320), which may cover the material 405 deposited in the trenches 325 and adjacent portions of the material 320.

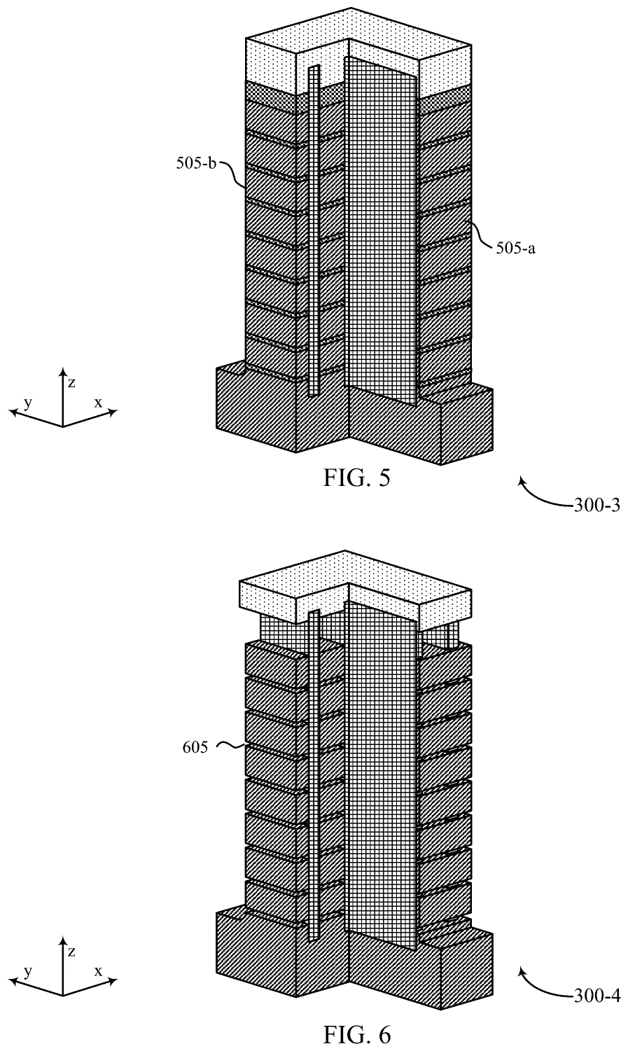

FIG. 5 illustrates the material arrangement 300 (e.g., as a material arrangement 300-3) after a third set of one or more fabrication operations. The third set of operations may include removing (e.g., trenching) at least a portion of the material arrangement 300 to form one or more sidewalls 505 (e.g., faces in respective xz-planes), such as the sidewall 505-a and the sidewall 505-b.

FIG. 6 illustrates the material arrangement 300 (e.g., as a material arrangement 300-4) after a fourth set of one or more fabrication operations. The fourth set of operations may include removing (e.g., exhuming) the material 315 to form one or more cavities 605 (e.g., between layers of the semiconductor material 310), which may involve an omnidirectional etching operation (e.g., a wet etching operation that preferentially removes the material 315). In some examples, the remaining layers of the semiconductor material 310 may be supported (e.g., along the z-direction) at least by the material 405 that was deposited in the trenches 325.

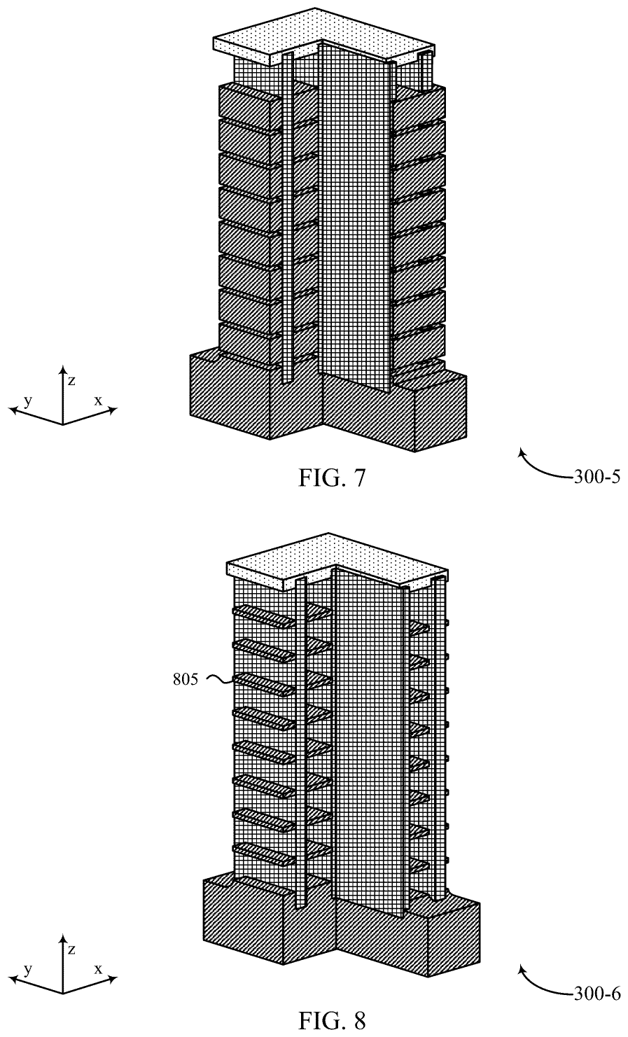

FIG. 7 illustrates the material arrangement 300 (e.g., as a material arrangement 300-5) after a fifth set of one or more fabrication operations. The fifth set of operations may include removing a portion of the material 410 (e.g., as a hard mask pull back operation). For example, the fifth set of operations may involve an etching operation (e.g., a partial wet etching operation, a partial directional etching operation oriented along the negative z-direction) that preferentially removes a portion of the material 410. In some examples, the fifth set of operations may thin the material 410 along the z-direction. Additionally, or alternatively, the fifth set of operations may pull back a sidewall of the material 410 (e.g., along the x-direction, along the y-direction, or both), which may reduce or remove an overhang of the material 410 (e.g., relative to portions of the material 405).

FIG. 8 illustrates the material arrangement 300 (e.g., as a material arrangement 300-6) after a sixth set of one or more fabrication operations. The sixth set of operations may include removing a portion of each layer of the semiconductor material 310 to form one or more layers 805 of the semiconductor material 310. For example, the sixth set of operations may involve an omnidirectional etching operation (e.g., a partial wet etching operation that preferentially removes portions of the semiconductor material 310). In some examples, the sixth set of operations may thin portions of the semiconductor material 310 along the z-direction (e.g., as a silicon thinning operation). Additionally, or alternatively, the sixth set of operations may pull back sidewalls of the semiconductor material 310 (e.g., along the y-direction), which may remove an overhang of the semiconductor material 310 (e.g., relative to portions of the material 405).

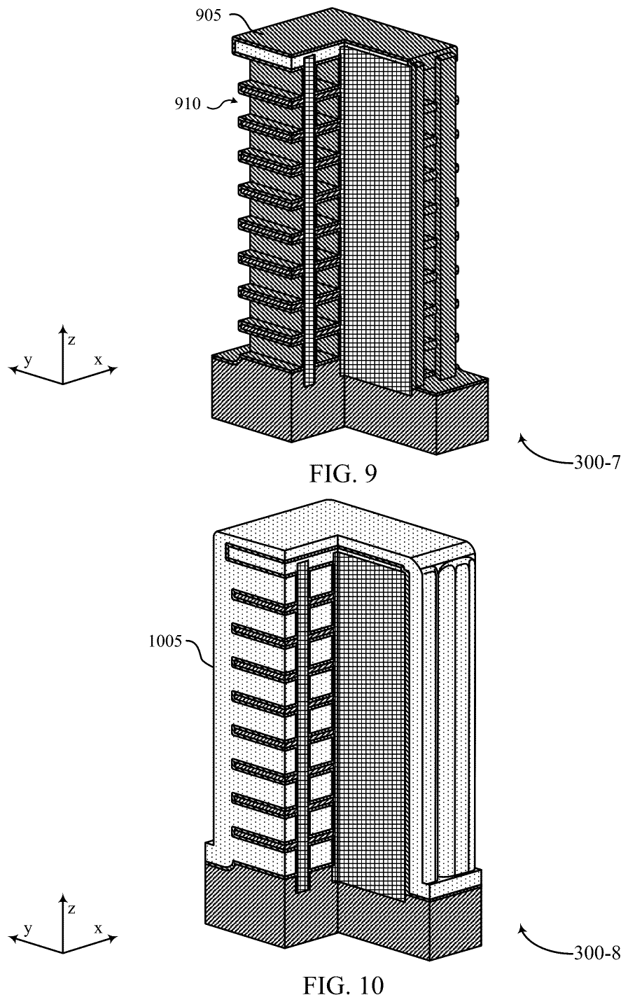

FIG. 9 illustrates the material arrangement 300 (e.g., as a material arrangement 300-7) after a seventh set of one or more fabrication operations. The seventh set of operations may include forming a material 905, which may include depositing (e.g., vapor depositing) the material 905 over the layers 805, the material 410, the substrate 305, or a combination thereof. In some examples, depositing the material 905 may be associated with forming (e.g., enclosing, in an xz-plane, along the y-direction) voids 910 in the material arrangement 300, which may refer to forming sidewall loops. In some examples, the material 905 may be a nitride material (e.g., as a nitride liner).

FIG. 10 illustrates the material arrangement 300 (e.g., as a material arrangement 300-8) after an eighth set of one or more fabrication operations. The eighth set of operations may include forming a material 1005, which may include depositing the material 1005 to at least fill the voids 910 among other portions of the material arrangement 300. In some examples, the material 1005 may be an oxide material, which may be the same as the material 320, the material 410, or both.

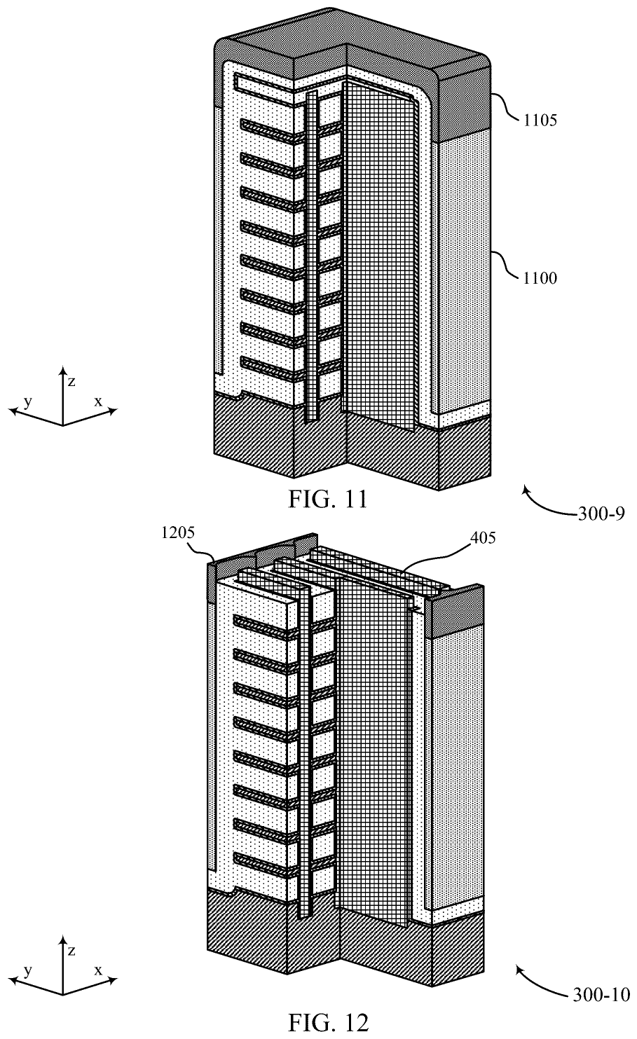

FIG. 11 illustrates the material arrangement 300 (e.g., as a material arrangement 300-9) after a ninth set of one or more fabrication operations. The ninth set of operations may include forming a material 1100. In some examples, the material 1100 may be formed by filling trenches with the material 1100 and recessing the deposited material 1100 (e.g., along the z-direction, relative to a surface of the material arrangement 300). In some examples, the material 1100 may be carbon (e.g., sacrificial carbon). The ninth set of operations may also include forming a material 1105 (e.g., over the recessed material 1100, which may isolate the material 1100 from downstream operations (e.g., as a protective cap). In some examples, the material 1105 may be a polysilicon material.

FIG. 12 illustrates the material arrangement 300 (e.g., as a material arrangement 300-10) after a tenth set of one or more fabrication operations. The tenth set of operations may include removing a portion of at least the material 1105, for example, which may include a planarization (e.g., CMP) operation that stops on a surface 1205. For example, the tenth set of operations may include removing an overburden of the material 1105. In some examples, the material removal operation may be configured to stop after reaching (e.g., exposing) a particular material, such as the material 405. Additionally, or alternatively, the planarization operation may be configured to stop on a different material, such as the material 1005 or the material 905 (e.g., as a stop on oxide, nitride, or carbon operation). For example, the tenth set of operations may also include performing a recess operation (e.g., a vapor etch recess) to remove a portion of the material 1005 and a portion of the material 905 to expose a portion of (e.g., sidewalls of) the material 405.

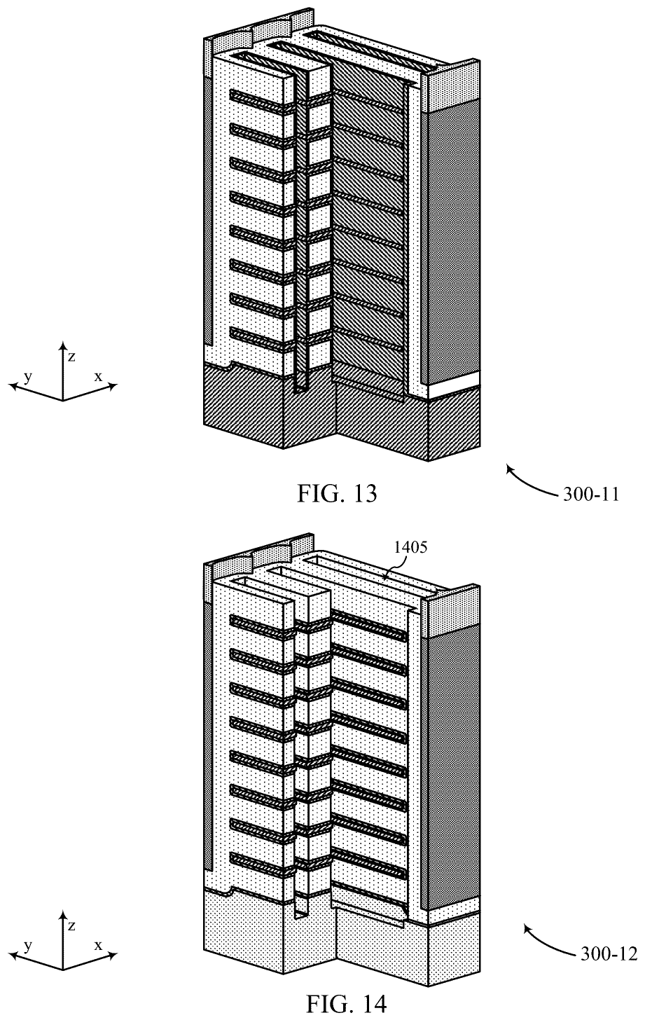

FIG. 13 illustrates the material arrangement 300 (e.g., as a material arrangement 300-11) after an eleventh set of one or more fabrication operations. The eleventh set of operations may include removing (e.g., exhuming) the material 405, which may involve an omnidirectional etching operation (e.g., a wet etching operation that preferentially removes the material 405). The eleventh set of operations may expose portions (e.g., sidewalls) of the material 905 and the semiconductor material 310 (e.g., along trenches 325).

FIG. 14 illustrates the material arrangement 300 (e.g., as a material arrangement 300-12) after a twelfth set of one or more fabrication operations. The twelfth set of operations may include removing (e.g., exhuming) portions of the material 905 (e.g., as a nitride liner loop chop operation), which may involve an omnidirectional etching operation (e.g., a wet etching operation that preferentially removes portions the material 905). The eleventh set of operations may form trenches 1405, which may include exposed portions (e.g., sidewalls) of the material 1005, the material 905, and the semiconductor material 310.

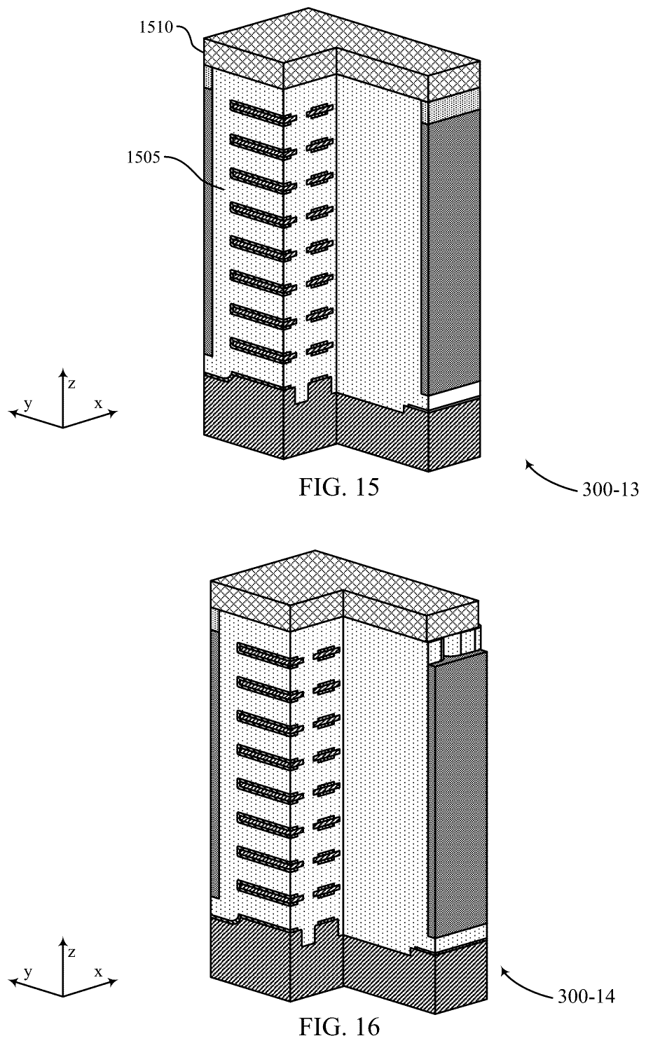

FIG. 15 illustrates the material arrangement 300 (e.g., as a material arrangement 300-13) after a thirteenth set of one or more fabrication operations. The thirteenth set of operations may include forming a material 1505 within and over the one or more trenches 1405. In some examples, the material 1505 may be a same material as the material 1005 (e.g., an oxide material). In some other examples, the material 1505 may be different material (e.g., a different oxide material). The thirteenth set of operations may also include forming a material 1510 to cover the material arrangement 300. In some examples, the material 1510 may be silicon oxycarbide (SiOC).

FIG. 16 illustrates the material arrangement 300 (e.g., as a material arrangement 300-14) after a fourteenth set of one or more fabrication operations. The fourteenth set of operations may include removing a portion of the material 1510 and a portion of the material 1105. In some examples, the material removal may include photolithography and a dry etching operation (e.g., to open trenches through the material 1510), and another material removal operation to remove the material 1105 (e.g., a wet etching operation, a wet cap removal operation).

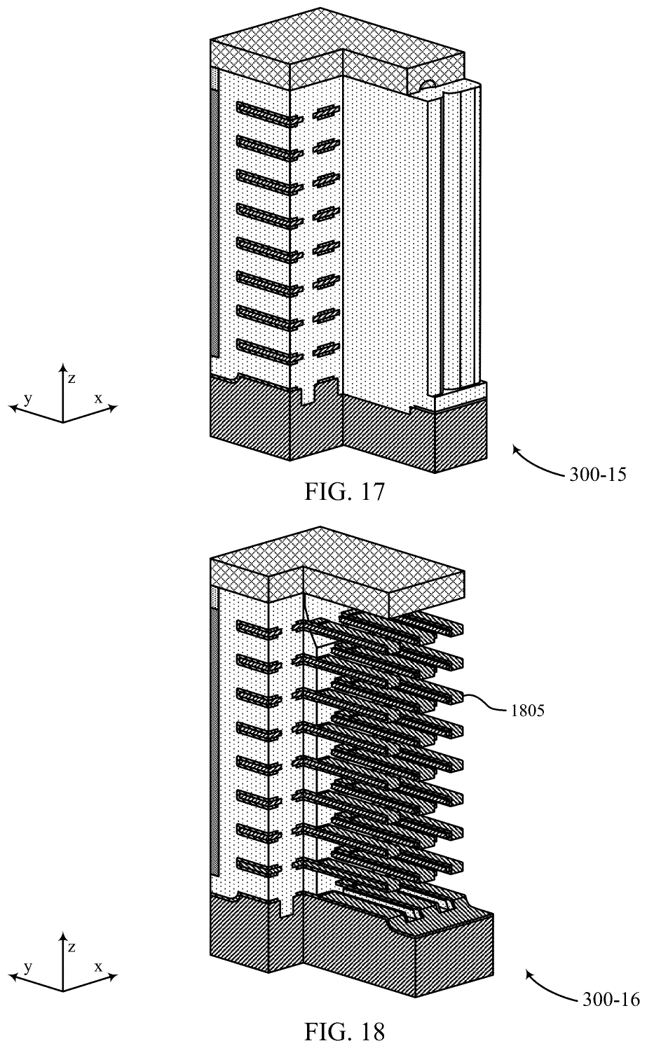

FIG. 17 illustrates the material arrangement 300 (e.g., as a material arrangement 300-15) after a fifteenth set of one or more fabrication operations. The fifteenth set of operations may include removing the material 1100 (e.g., a carbon strip operation), which may expose sidewalls of the material 1005. In some examples, the removal of the material 1100 may be followed by an annealing operation.

FIG. 18 illustrates the material arrangement 300 (e.g., as a material arrangement 300-16) after a sixteenth set of one or more fabrication operations. The sixteenth set of operations may include removing a portion of the material 1005 to expose one or more studs 1805 (e.g., studs of semiconductor material 310 and material 905). For example, the sixteenth set of operations may include performing a recess operation (e.g., an oxide recess operation) to release the one or more studs 1805 (e.g., for word line formation). Each stud 1805 may include a portion of the semiconductor material 310, which may be covered, at least partially, with a portion of the material 905. In some examples, the material removal of the sixteenth set of operations may establish a boundary (e.g., along the y-direction, as sidewalls of the material 1005 generally in an xz-plane) between transistors 260 and capacitors 250 formed from the material arrangement 300.

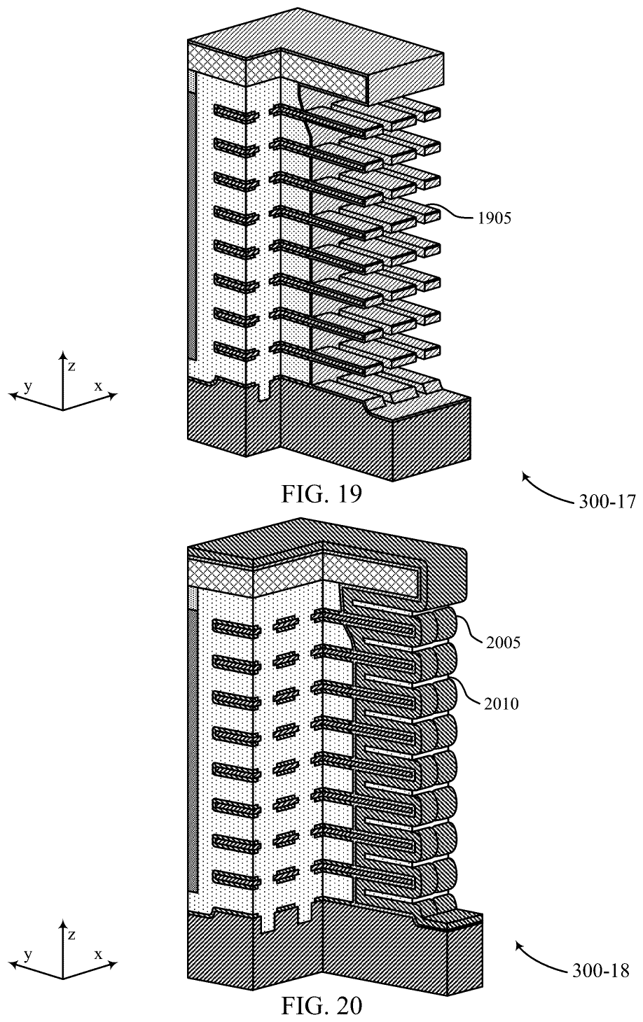

FIG. 19 illustrates the material arrangement 300 (e.g., as a material arrangement 300-17) after a seventeenth set of one or more fabrication operations. The seventeenth set of operations may include forming a material 1905 (e.g., a dielectric material) around portions of the semiconductor material 310 (e.g., a portion included in the one or more studs 1805) and along the exposed sidewalls of the material 1005. In some examples, the material 1905 may be SiCO. In some examples, the seventeenth set of operations may include removing (e.g., at least partially) exposed portions of the material 905 from the studs 1805. Thus, in some examples, the material 1905 may be deposited in contact with (e.g., directly, around) portions of the semiconductor material 310.

The material 1905 may support aspects of self-alignment for forming features of capacitors 250 as part of subsequent fabrication operations. For example, the material 1905 may act as an etch-stop for one or more material removal operations (e.g., a surface on which a material removal operation may be configured to stop). Accordingly, the material 1905 may form one or more aligned surfaces (e.g., including surfaces generally in an xz-plane) that may provide alignment (e.g., along the y-direction) for the capacitors 250.

FIG. 20 illustrates the material arrangement 300 (e.g., as a material arrangement 300-18) after an eighteenth set of one or more fabrication operations. The eighteenth set of operations may include forming a material 2005 and a material 2010 that covers the material 1905. Each of the material 2005 and the material 2010 may be a dielectric material and, in some examples, the material 2005 may be a nitride material and the material 2010 may be an oxide material (e.g., a same material as the material 1005, among others). In some examples, the material 2010 may be deposited in manner that covers the material 2005, and then may be recessed to expose portions of the material 2005.

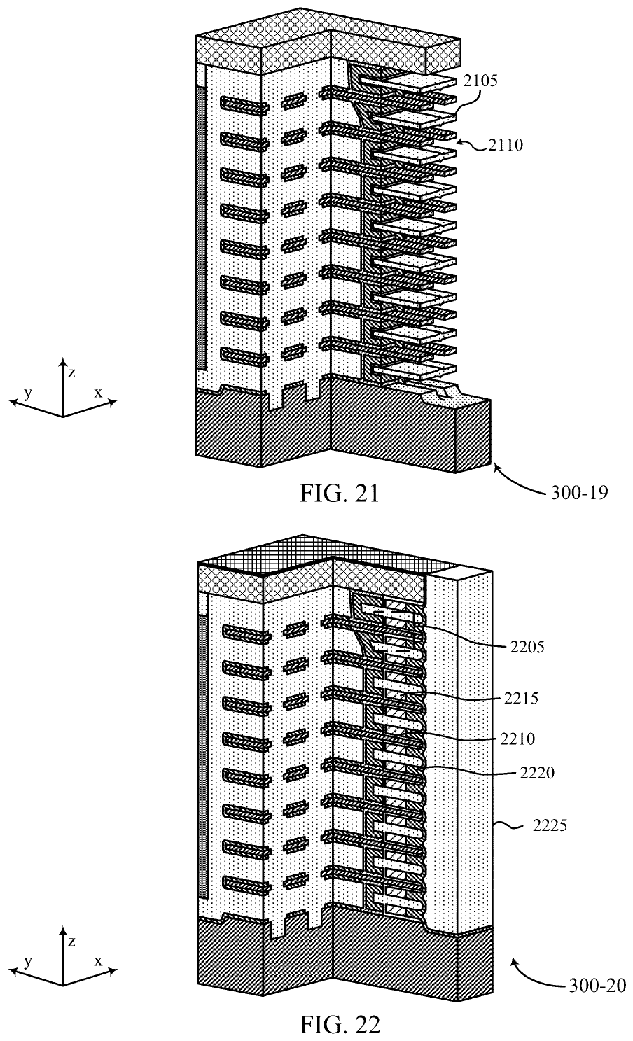

FIG. 21 illustrates the material arrangement 300 (e.g., as a material arrangement 300-19) after a nineteenth set of one or more fabrication operations. The nineteenth set of operations may include removing portions of at least the material 2005 and the material 1905, which may expose portions of the semiconductor material 310 of the studs 1805. In some examples, the nineteenth set of operations may include oxidizing at least some of the material 1905 and removing the oxidized material 1905 (e.g., oxidizing SiOC into SiO₂ and then removing the SiO₂). The nineteenth set of operations may also form layers 2105 of the material 2010 (e.g., portions generally contiguous along xy-planes), which may form boundaries (e.g., insulation regions) between cavities 2110 extending along the x-direction, within which word lines 120 may be formed.

FIG. 22 illustrates the material arrangement 300 (e.g., as a material arrangement 300-20) after a twentieth set of one or more fabrication operations. The twentieth set of operations may include aspects of forming one or more cell selection transistors 2205, which may be examples of transistors 260. For example, the twentieth set of operations may include forming a material 2210 (e.g., a dielectric material) on the exposed portions of the semiconductor material 310, which may form a gate dielectric for the transistors 2205. In some examples, the material 2210 may be an oxide material (e.g., a gate oxide), which may be the same material as the material 2010. The twentieth set of operations may also include forming a material 2215 (e.g., a conductor material), which may form a gate (e.g., a gate conductor) for the transistors 2205. In some examples, contiguous portions of the material 2215 may each be associated with (e.g., form at least a portion of) a word line 120. The twentieth set of operations may also include forming the material 2220 (e.g., a dielectric material). In some examples, the material 2220 may be the same material as the material 2005 (e.g., a nitride material). In some cases, the set of operations may further include forming a material 2225 (e.g., a dielectric material), which may be the same material as the material 1005 (e.g., an oxide material), among others.

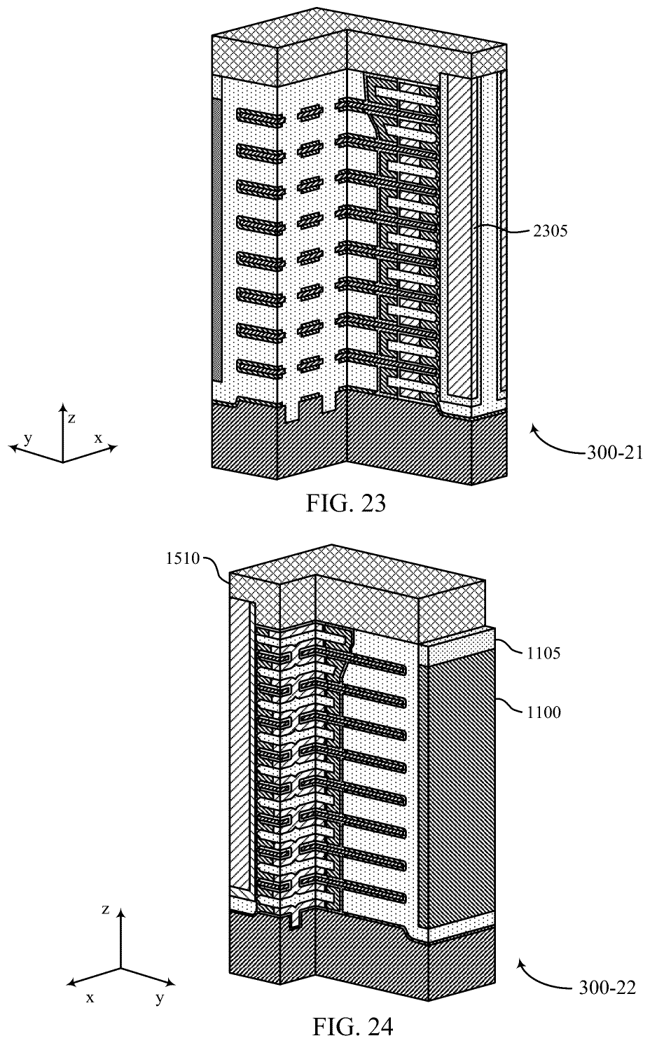

FIG. 23 illustrates the material arrangement 300 (e.g., as a material arrangement 300-21) after a twenty-first set of one or more fabrication operations. The twenty-first set of operations may include forming a material 2305 (e.g., one or more conductive materials, which may include an electrode liner and a bulk conductive material). In some examples, the material 2305 may be the same material as the material 2215. In some examples, contiguous portions of the material 2305 may each be associated with (e.g., form at least a portion of) a digit line 130.

FIG. 24 illustrates the material arrangement 300 (e.g., as a material arrangement 300-22) after a twenty-second set of one or more fabrication operations (e.g., with a diagonal view that is rotated about the z-axis relative to the diagonal views of FIGS. 3 through 24). The twenty-second set of operations may include removing a portion of the material 1510, such as by using photolithography, a dry etching operation, or a combination thereof (e.g., as a hard mask opening operation, as a trenching operation). In some examples, the material removal operations may stop on the material 1105.

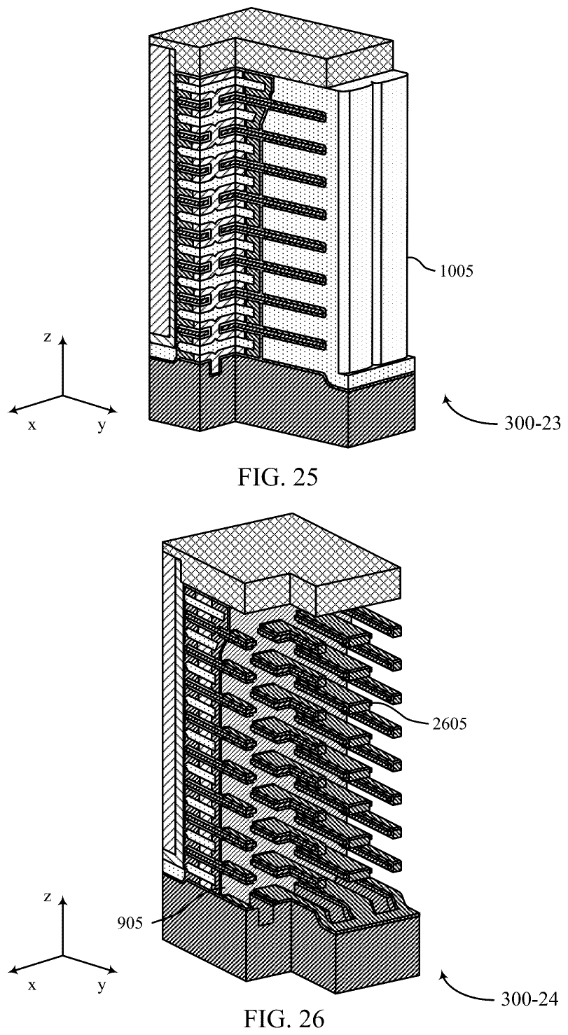

FIG. 25 illustrates the material arrangement 300 (e.g., as a material arrangement 300-23) after a twenty-third set of one or more fabrication operations. The twenty-third set of operations may include removing exposed portions of the material 1105 and the material 1100 (e.g., in an etching operation, such as a wet etch, a carbon strip operation, an exhume operation), which may expose sidewalls of the material 1005. In some examples, the twenty-third set of operations may also include an operation that further removes some of the material 1510 (e.g., along the y-direction, a hard mask pull back operation).

FIG. 26 illustrates the material arrangement 300 (e.g., as a material arrangement 300-24) after a twenty-fourth set of one or more fabrication operations. The twenty-fourth set of operations may include removing at least a portion of the material 1005 (e.g., an oxide recess operation, an exhume operation), which may expose studs 2605. For example, the sixteenth set of operations may include performing a recess operation to expose sidewalls of the material 1905, portions of the semiconductor material 310, and portions of the material 905, and thus release the studs 2605. Each stud 2605 may include a portion of the semiconductor material 310, which may be covered, at least partially, with a portion of the material 905. In some examples, the recess operation may be configured to stop on the material 1905, which may expose sidewalls (e.g., surfaces generally in an xz-plane) of the material 1905. Thus, the exposed surfaces of the material 1905 may provide a self-alignment feature (e.g., an alignment along the y-direction, an etch stop) relative to transistors 2205, which may support self-alignment along the y-direction for forming features of capacitors 250 during subsequent fabrication operations.

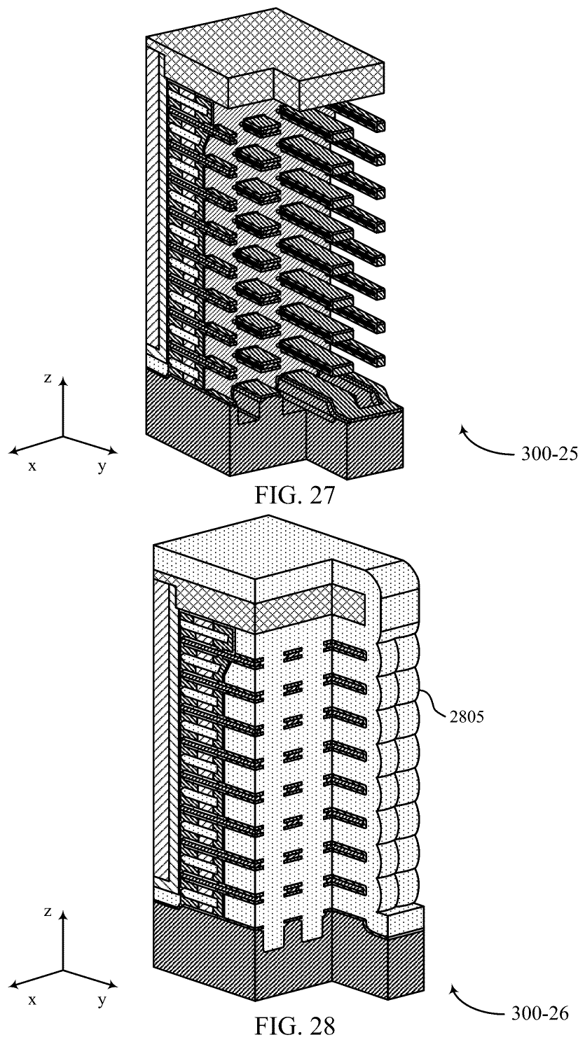

FIG. 27 illustrates the material arrangement 300 (e.g., as a material arrangement 300-25) after a twenty-fifth set of one or more fabrication operations. The twenty-fifth set of operations may include removing some of exposed sidewalls of the semiconductor material 310. For example, the twenty-fifth set of operations may include performing an etching operation that reduces the width (e.g., along the x-direction) of the studs 2605 (e.g., in a stud trimming operation).

FIG. 28 illustrates the material arrangement 300 (e.g., as a material arrangement 300-26) after a twenty-sixth set of one or more fabrication operations. The twenty-sixth set of operations may include forming a material 2805 (e.g., a dielectric material) around the studs 2605 (e.g., around the semiconductor material 310 and the material 905) and in contact with the material 1905 (e.g., in an oxide mesh deposition operation). In some examples, the material 2805 may be an oxide material, which may be the same as the material 2010.

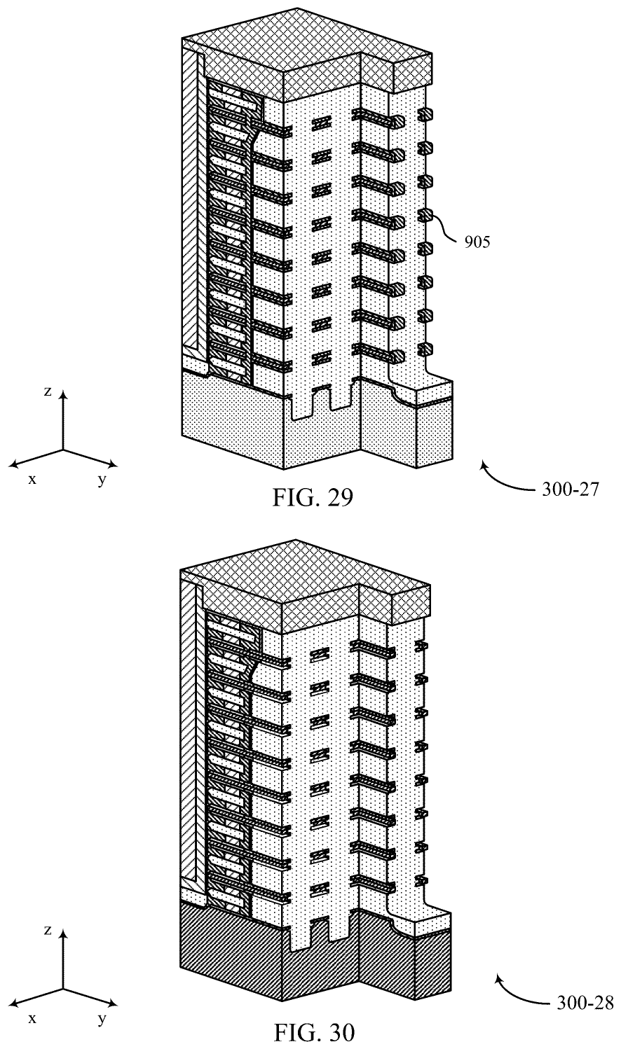

FIG. 29 illustrates the material arrangement 300 (e.g., as a material arrangement 300-27) after a twenty-seventh set of one or more fabrication operations. The twenty-seventh set of operations may include removing a portion of the material 2805 to expose respective ends of each of the studs 2605. For example, the twenty-seventh set of operations may include an oxide recess operation that exposes the material 905 at the ends of the studs 2605.

FIG. 30 illustrates the material arrangement 300 (e.g., as a material arrangement 300-28) after a twenty-eighth set of one or more fabrication operations. The twenty-eighth set of operations may include removing exposed portions of the material 905 (e.g., an SiN liner removal operation, an exhume operation, a stop on film process, a nitride recess stop on SiOC operation). The twenty-eighth set of operations may expose portions of the semiconductor material 310 and surrounding portions (e.g., sidewalls) of the material 1905.

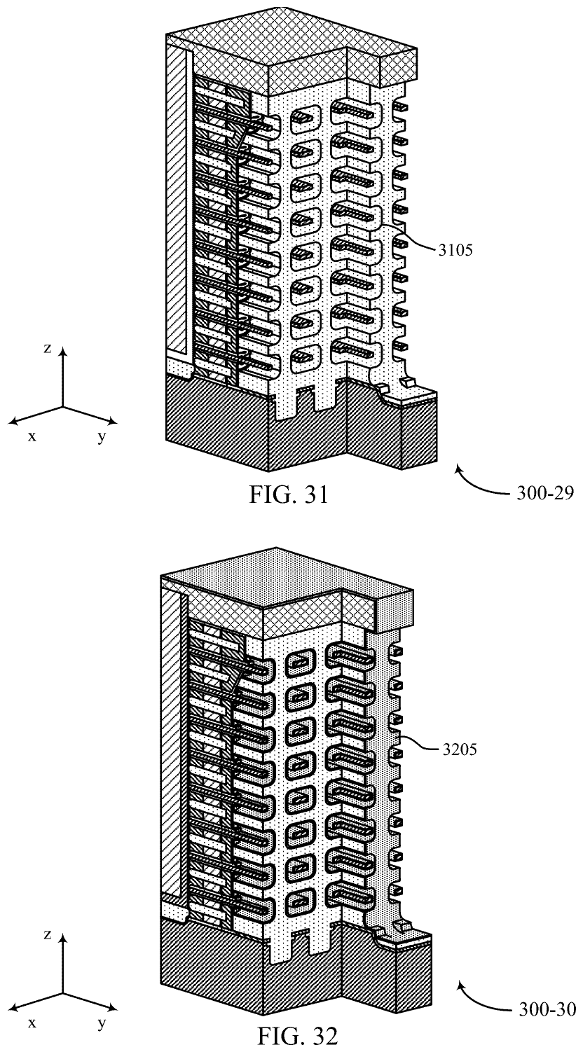

FIG. 31 illustrates the material arrangement 300 (e.g., as a material arrangement 300-29) after a twenty-ninth set of one or more fabrication operations. The twenty-ninth set of operations may include forming cavities 3105, such as by removing portions of the material 2805 (e.g., along studs 2605). Forming the cavities 3105 may expose a portion of the semiconductor material 310, may expose sidewalls of the material 1905 (e.g., for enclosing features of respective capacitors 250 in an xz-plane), or both.

In some examples, the twenty-ninth set of operations may include doping the exposed portions of the semiconductor material 310. For example, for transistors 260 having an n-type configuration, the twenty-ninth set of operations may include doping the exposed semiconductor material 310 (e.g., ends of the semiconductor material, of the exposed studs) with an n-type doping material (e.g., using a gas phase doping operation, using diffusion doping from a sacrificial material, or a combination thereof). Doping the ends of the semiconductor material 310 may form a concentration of an n-type dopant (e.g., a concentration greater than 1e18 per cubic centimeter (cm), a concentration greater than 1e20 per cubic cm, a concentration greater than 1e21 per cubic cm). In some examples, the twenty-ninth set of operations or other operations may include doping other portions of the semiconductor material 310 (e.g., in the channel regions of the transistors 260, between n-type doped portions) with a p-type doping material (e.g., to provide an NPN transistor junction).

FIG. 32 illustrates the material arrangement 300 (e.g., as a material arrangement 300-30) after a thirtieth set of one or more fabrication operations. The thirtieth set of operations may include forming electrodes 210. For example, the thirtieth set of operations may include forming a material 3205 (e.g., a conductive material, such as titanium nitride (TiN)) at least in the cavities 3105. In some examples, the material 3205 may include first portions over each of the portions of semiconductor material 310, second portions along the sidewalls of the material 1005 (e.g., concentric with the first portions of the material 3205), and third portions coupling the first portions of the material 3205 with the second portions of the material 3205 (e.g., in contact with respective portions of the material 1905, for an aspect of self-alignment). In some examples, the third portions may have an irregularity (e.g., a kink, pointing radially inward toward the studs of semiconductor material 310) associated with an oxide mesh protrusion between capacitors 250. The respective portions of material 3205 within each cavity 3105 may form a respective electrode 210. For example, the material 3205 deposited on the semiconductor material 310 may form a portion 220-a and the material 3205 deposited on sidewalls of the cavities 3105 may form a portion 220-b.

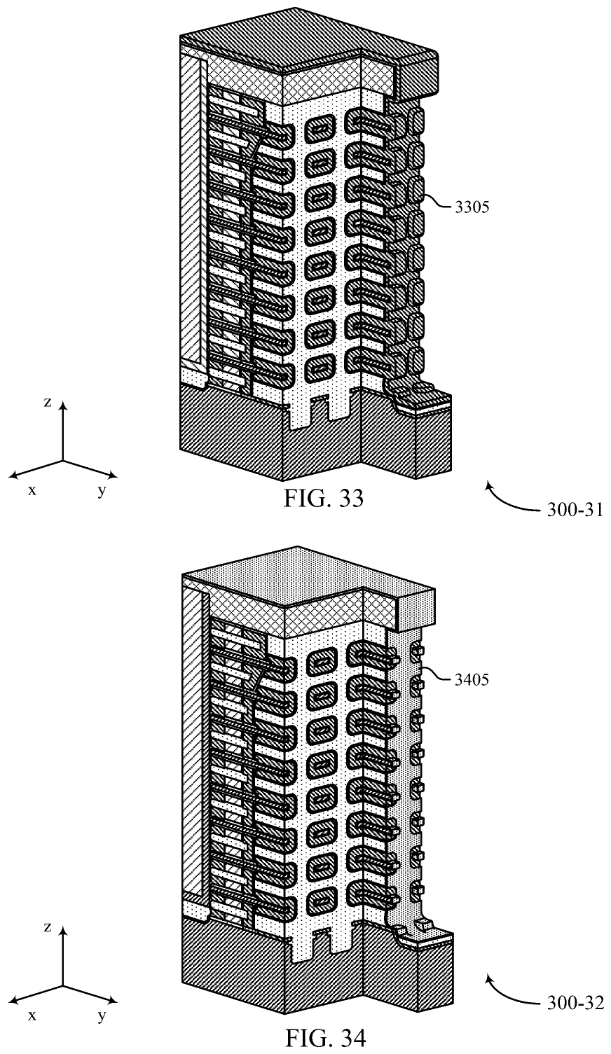

FIG. 33 illustrates the material arrangement 300 (e.g., as a material arrangement 300-31) after a thirty-first set of one or more fabrication operations. The thirty-first set of operations may include forming a material 3305, which may be a sacrificial material such as a nitride, in contact with the material 3205. For example, the thirty-first set of operations may include depositing the material 3305 to fill the one or more cavities 3105. Forming the material 3305 may cover one or more sidewalls of the material 3205 and enclose the cavities 3105 over ends of the studs 2605.

FIG. 34 illustrates the material arrangement 300 (e.g., as a material arrangement 300-32) after a thirty-second set of one or more fabrication operations. The thirty-second set of operations may include removing portions of the material 3305 (e.g., as a nitride recess operation) to expose sidewalls of the material 3205 (e.g., exposing the material 3205 at ends of the studs 2605 and along a surface 3405 in an xz-plane, exposing TiN loops), while retaining portions of the material 3305 that fill at least a portion of the cavities 3105.

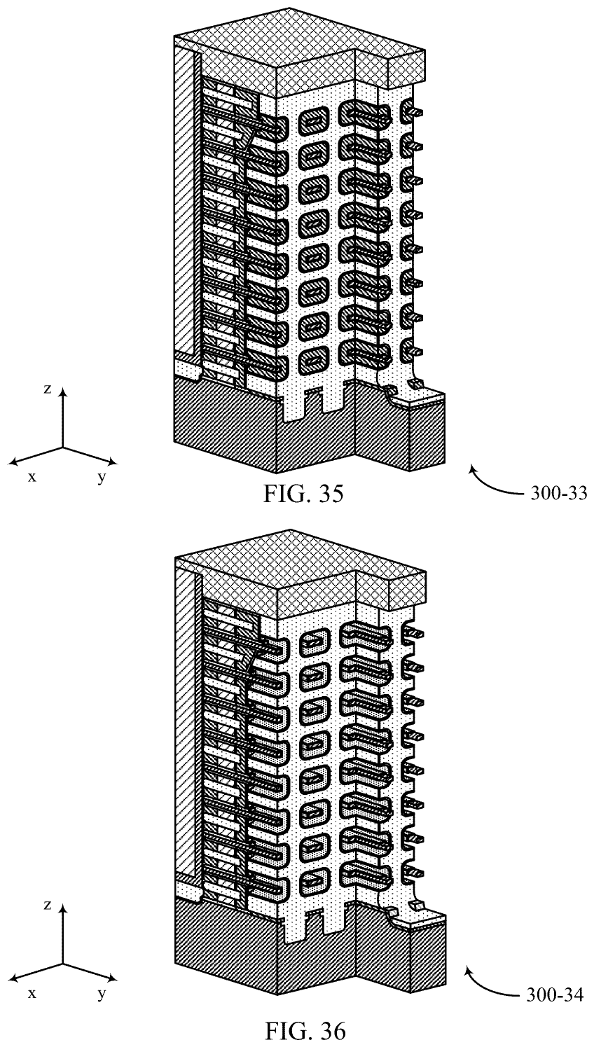

FIG. 35 illustrates the material arrangement 300 (e.g., as a material arrangement 300-33) after a thirty-third set of one or more fabrication operations. The thirty-third set of operations may include removing portions of the material 3205 after removing portions of the material 3305 (e.g., as a TiN recess operation). For example, the thirty-third set of operations may include removing the material 3205 from surface 3405 over the material 1105 and the material 3305 (e.g., generally surfaces in xz-planes) and from around the semiconductor material 310 and, in some examples, recessing (e.g., along the y-direction) the material 3205 between the semiconductor material 310 and the material 3305. Removing the portions of the material 3205 may separate the material 3205 within each cavity 3105 from the material 3205 within a different cavity 3105 (e.g., to separate electrodes 210 of adjacent capacitors 250). For example, the set of operations may include a recess operation to remove an outer sidewall of the material 3205 to expose the material 2805.

FIG. 36 illustrates the material arrangement 300 (e.g., as a material arrangement 300-34) after a thirty-fourth set of one or more fabrication operations. The thirty-fourth set of operations may include removing (e.g., exhuming) the material 3305 from the one or more cavities 3105 (e.g., in a sacrificial film removal operation), which may involve an omnidirectional etching operation (e.g., a wet etching operation that preferentially removes the material 3305). For example, the thirty-fourth set of operations may include removing the material 3305 using an operation configured to stop on the material 3205, which may expose portions of the material 3205 (e.g., exposing sidewalls, such as interior sidewalls, of conductor portions of electrodes 210).

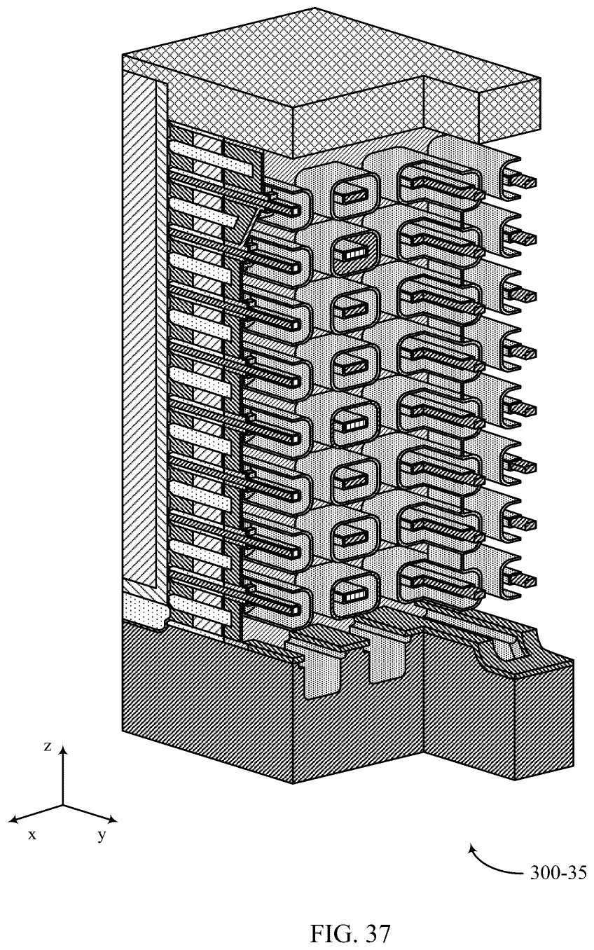

FIG. 37 illustrates the material arrangement 300 (e.g., as a material arrangement 300-35) after a thirty-fifth set of one or more fabrication operations. The thirty-fifth set of operations may include removing portions of the material 2805, which may involve an omnidirectional etching operation (e.g., a wet etching operation that preferentially removes the material 2805). For example, the thirty-fifth set of operations may include recessing the material 2805 to expose other portions of the material 3205 (e.g., exposing sidewalls, such as exterior sidewalls, of conductor portions of electrodes 210 between capacitors 250).

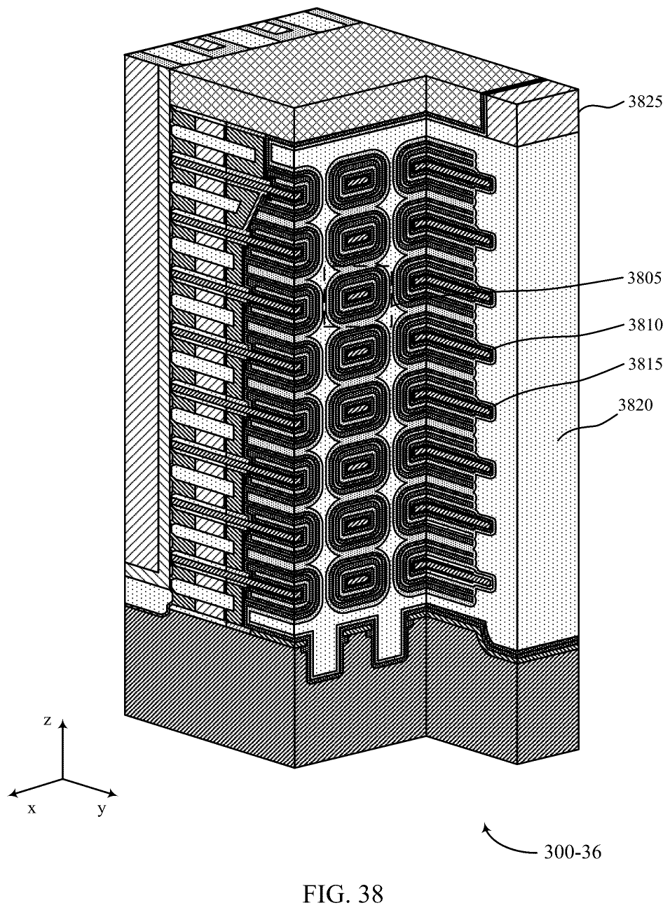

FIG. 38 illustrates the material arrangement 300 (e.g., as a material arrangement 300-36) after a thirty-sixth set of one or more fabrication operations. The thirty-sixth set of operations may include operations that support forming electrodes 215 and dielectric material between the electrodes 215 and the electrodes 210. For example, the thirty-sixth set of operations may include forming a material 3810 (e.g., a dielectric material) on the exposed portions of the material 3205 (e.g., on the exposed portions of the electrode 210). Additionally, the thirty-sixth set of operations may include forming a material 3815 (e.g., a conductor material) on exposed portions the material 3810.

The material 3810 may be an example of a dielectric material, which may have a relatively high dielectric constant (e.g., a relative to other insulating materials of the material arrangement 300), and accordingly may be referred to as a high-k material. In some examples, the material 3810 may have ferroelectric properties, which may support operation in accordance with a ferroelectric capacitance. The material 3815 may be an example of a conductive material such as titanium nitride and may act as electrodes for memory cells 105 (e.g., electrodes 215). Accordingly, the thirty-sixth set of operations may form capacitors 3805 (e.g., capacitors 250) of the memory cells 105, for which the material 3205 may support first plates (e.g., electrodes 210) of the capacitors 3805, the material 3815 may support second plates (e.g., electrodes 215) of the capacitors 3805, and the material 3810 may support a dielectric film between the first plates and the second plates. In some examples, such techniques may be associated with forming three-sided stud capacitors 3805, for which at least a portion of the material 3815 may be deposited along the y-direction between adjacent capacitors 3805 (e.g., as portions 225-b between adjacent capacitors 3805 along the x-direction, along the z-direction, or both). In some examples, such techniques may be associated with forming two-sided stud capacitors 3805, for which the material 3815 is not deposited along the y-direction between adjacent capacitors (e.g., omitting portions 225-b), such as when the material 3810 fills such portions between capacitors 3805 (e.g., along the x-direction, along the z-direction, or both).

In some cases, the thirty-sixth set of operations may include forming a conductive plate line 140-a (e.g., a conductive plate) extending along the x-direction, or the z-direction, or both, and a contact 3825 arranged above (e.g., along the z-direction, on top of the plate line 140-a). For example, thirty-sixth set of operations may include depositing a material 3820 to contact the material 3815, which may form the plate line 140-a, and depositing a second conducive material to form the contact 3825. In some cases, the material 3820 may be different than the material of the electrode 210 (e.g., material 3205), the electrode 215 (e.g., material 3815), or both. For example, the material 3820 may include boron, silicon, germanium, or a combination thereof, such as a boron silicon germanium alloy.

Thus, the operations for forming the material arrangement 300 illustrated in FIGS. 3 through 38 provide examples for forming an apparatus (e.g., a memory apparatus, a semiconductor component, a memory die) in accordance with various memory architectures, such as the array architecture 200. For example, the material arrangement 300 illustrates an example for a cell selection transistor 2205 (e.g., a transistor 260, of a memory cell 105), a channel of the cell selection transistor 2205 comprising a first portion of the semiconductor material 310 (e.g., a portion of a semiconductor material 310 along a negative y-direction from the material 1905) extending along a first direction (e.g., extending along the y-direction) over a substrate 305. The material arrangement 300 also illustrates a capacitor 3805 (e.g., a capacitor 250, of the memory cell 105) coupled with the channel of the cell selection transistor 2205 and associated with an axis (e.g., an axis 255) along the first direction. The capacitor 3805 may be associated with (e.g., may include): a first portion of a first electrode (e.g., a portion 220-a of an electrode 210, a first portion of the material 3205) around a second portion of the semiconductor material 310 (e.g., a portion of the semiconductor material 310 along a positive y-direction from the material 1905) about the axis; a first portion of a first dielectric (e.g., a portion of the material 3810) of the capacitor around the first portion of the first electrode about the axis; a portion of a second electrode of the capacitor (e.g., a portion 225-a of an electrode 215, a portion of the material 3815) around the first portion of the first dielectric about the axis; a second portion of the first dielectric (e.g., a portion of the material 3810) around the second electrode about the axis; a second portion of the first electrode (e.g., a portion 220-b of the electrode 210) around the second portion of the first dielectric about the axis; and a second dielectric (e.g., material 1905) between the cell selection transistor and the capacitor along the first direction and around the semiconductor material between the first portion of the semiconductor material and the second portion of the semiconductor material.

Because the set of fabrication operations include the aligned surfaces (e.g., surfaces aligned along the y-direction) of the material 1905, forming features of the capacitors 3805 on the surfaces of the material 1905 may result in self-alignment for the capacitors 3805. For example, forming the material 3205 may include forming respective electrodes 210 for each of the capacitors 3805. Because a portion of the material 3205 (e.g., sidewalls of the material 3205) may be formed on the surfaces of the material 1905, the electrodes 210 may be aligned along the y-direction, which may support a relatively dense array architecture (e.g., along at least the y-direction), relatively high storage capacity, relatively low fabrication cost, or relatively low operational latency, among other benefits.

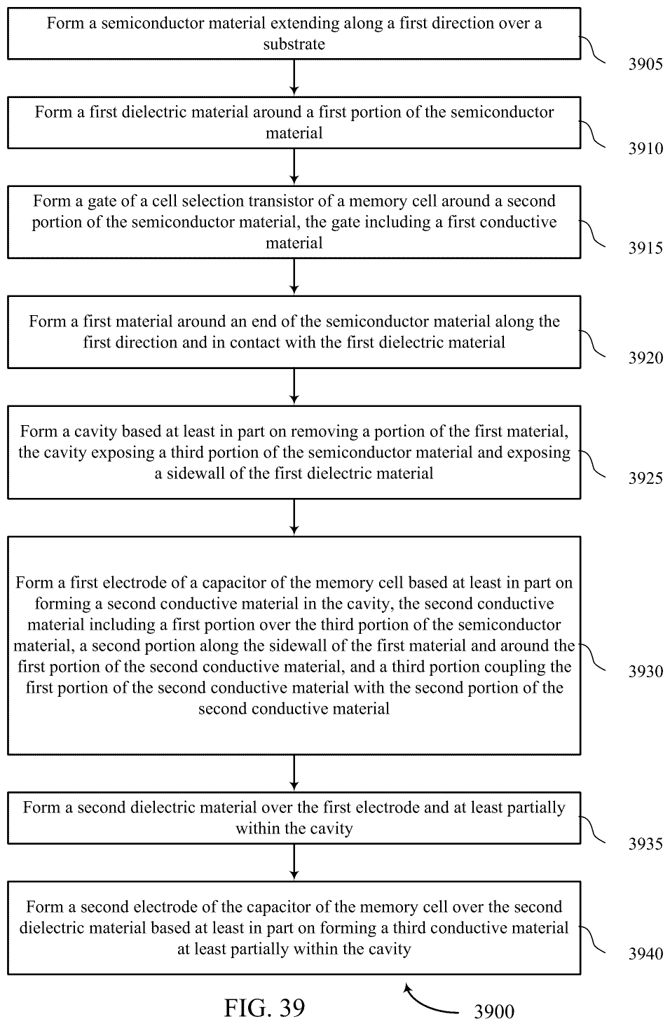

FIG. 39 shows a flowchart illustrating a method 3900 that supports self-aligned capacitors for three-dimensional memory systems in accordance with examples as disclosed herein. The operations of method 3900 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 3905, the method may include forming a semiconductor material (e.g., one or more portions of a semiconductor material 310) extending along a first direction over a substrate (e.g., a substrate 305).

At 3910, the method may include forming a first dielectric material (e.g., material 1905) around a first portion of the semiconductor material.

At 3915, the method may include forming a gate of a cell selection transistor (e.g., a transistor 260, a transistor 2205) of a memory cell around a second portion of the semiconductor material, the gate including a first conductive material (e.g., material 2215).

At 3920, the method may include forming a first material (e.g., material 1005) around an end of the semiconductor material along the first direction and in contact with the first dielectric material.

At 3925, the method may include forming a cavity (e.g., a cavity 3105) based at least in part on removing a portion of the first material, the cavity exposing a third portion of the semiconductor material and exposing a sidewall of the first dielectric material.

At 3930, the method may include forming a first electrode of a capacitor (e.g., an electrode 210 of a capacitor 3805) of the memory cell based at least in part on forming a second conductive material (e.g., material 3205) in the cavity, the second conductive material including a first portion over the third portion of the semiconductor material, a second portion along the sidewall of the first material and around the first portion of the second conductive material, and a third portion coupling the first portion of the second conductive material with the second portion of the second conductive material.

At 3935, the method may include forming a second dielectric material (e.g., material 3810) over the first electrode and at least partially within the cavity.

At 3940, the method may include forming a second electrode (e.g., an electrode 215) of the capacitor of the memory cell over the second dielectric material based at least in part on forming a third conductive material (e.g., material 3815) at least partially within the cavity.

In some examples, an apparatus (e.g., a manufacturing system) as described herein may perform a method or methods, such as the method 3900. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:
Aspect 1: A method or apparatus including operations, features, circuitry, logic, means, or instructions, or any combination thereof for forming a semiconductor material extending along a first direction over a substrate; forming a first dielectric material around a first portion of the semiconductor material; forming a gate of a cell selection transistor of a memory cell around a second portion of the semiconductor material, the gate including a first conductive material; forming a first material around an end of the semiconductor material along the first direction and in contact with the first dielectric material; forming a cavity based at least in part on removing a portion of the first material, the cavity exposing a third portion of the semiconductor material and exposing a sidewall of the first dielectric material; forming a first electrode of a capacitor of the memory cell based at least in part on forming a second conductive material in the cavity, the second conductive material including a first portion over the third portion of the semiconductor material, a second portion along the sidewall of the first material and around the first portion of the second conductive material, and a third portion coupling the first portion of the second conductive material with the second portion of the second conductive material; forming a second dielectric material over the first electrode and at least partially within the cavity; and forming a second electrode of the capacitor of the memory cell over the second dielectric material based at least in part on forming a third conductive material at least partially within the cavity.
Aspect 2: The method or apparatus of aspect 1, further including operations, features, circuitry, logic, means, or instructions, or any combination thereof for exposing a portion of the sidewall of the first dielectric material, a portion of the semiconductor material, and a portion of a nitride material (e.g., material 905) over the semiconductor material based at least in part on removing a second material and removing the exposed portion of the semiconductor material, where forming the first material is performed after removing the exposed portion of the semiconductor material.
Aspect 3: The method or apparatus of aspect 2, further including operations, features, circuitry, logic, means, or instructions, or any combination thereof for exposing a portion of the first dielectric material based at least in part on removing the portion of the nitride material, where forming the cavity exposes the portion of the first dielectric material.
Aspect 4: The method or apparatus of any of aspects 1 through 3, further including operations, features, circuitry, logic, means, or instructions, or any combination thereof for forming a nitride material (e.g., material 3305) in contact with the second conductive material and filling the cavity and removing a portion of the second conductive material after removing the nitride material, where removing the portion of the second conductive material exposes a portion of the first material.
Aspect 5: The method or apparatus of aspect 4, further including operations, features, circuitry, logic, means, or instructions, or any combination thereof for removing the nitride material from the cavity, where forming the second dielectric material is performed after removing the nitride material.
Aspect 6: The method or apparatus of any of aspects 1 through 5, further including operations, features, circuitry, logic, means, or instructions, or any combination thereof for exposing an end of the semiconductor material based at least in part on removing a portion of the second conductive material, where forming the second dielectric material is performed after exposing the end of the semiconductor material.
Aspect 7: The method or apparatus of any of aspects 1 through 6, where the second dielectric material is formed over an end of the semiconductor material.

An apparatus is described. The following provides an overview of aspects of the apparatus as described herein:
Aspect 8: An apparatus, including: a cell selection transistor (e.g., a transistor 260, a transistor 2205) of a memory cell, a channel of the cell selection transistor including a first portion of a semiconductor material (e.g., a semiconductor material 310) extending along a first direction (e.g., a y-direction) over a substrate (e.g., a substrate 305); a capacitor (e.g., a capacitor 250, a capacitor 3805) of the memory cell coupled with the channel of the cell selection transistor and associated with an axis along the first direction, the capacitor including: a first portion of a first electrode (e.g., an electrode 215) of the capacitor around a second portion of the semiconductor material about the axis, a first portion of a first dielectric (e.g., a material 3810) of the capacitor around the first portion of the first electrode about the axis, a portion of a second electrode (e.g., an electrode 215) of the capacitor around the first portion of the first dielectric about the axis, a second portion of the first dielectric around the second electrode about the axis; and a second portion of the first electrode around the second portion of the first dielectric about the axis; and a second dielectric (e.g., a material 1905) between the cell selection transistor and the capacitor along the first direction and around the semiconductor material between the first portion of the semiconductor material and the second portion of the semiconductor material.
Aspect 9: The apparatus of aspect 8, where the first portion of the first electrode is contiguous with the second portion of the first electrode via a third portion of the first electrode that is in contact with the second dielectric.
Aspect 10: The apparatus of aspect 9, further including: a fourth portion of the first dielectric contiguous with the third portion of the first dielectric and over and end of the second portion of the second electrode, the fourth portion of the first dielectric in contact with the second dielectric.
Aspect 11: The apparatus of any of aspects 9 through 10, where the second portion of the first dielectric is contiguous with the third portion of the first dielectric over an end of the second portion of the first electrode.
Aspect 12: The apparatus of any of aspects 8 through 11, further including: a third portion of the first dielectric around the second portion of the first electrode about the axis; and a second portion of the second electrode around the third portion of the first dielectric about the axis.
Aspect 13: The apparatus of any of aspects 8 through 12, where the first portion of the first dielectric is contiguous with the second portion of the first dielectric over an end of the portion of the second electrode.
Aspect 14: The apparatus of any of aspects 8 through 13, where the first portion of the first dielectric is contiguous over an end of the second portion of the semiconductor material.
Aspect 15: The apparatus of any of aspects 8 through 14, where the portion of the second electrode is contiguous over an end of the second portion of the semiconductor material.
Aspect 16: The apparatus of any of aspects 8 through 15, where the first portion of the first electrode is noncontiguous over an end of the second portion of the semiconductor material.
Aspect 17: The apparatus of any of aspects 8 through 16, further including: a third dielectric between a gate of the cell selection transistor and the channel, the third dielectric in contact with the second dielectric.
Aspect 18: The apparatus of aspect 17, where an interface between the second dielectric and the third dielectric includes a grain boundary.
Aspect 19: The apparatus of any of aspects 8 through 18, further including: a fourth dielectric between the gate of the cell selection transistor and the second dielectric, where the fourth dielectric is in contact with the second dielectric.
Aspect 20: The apparatus of aspect 19, where the fourth dielectric includes a nitride material that is different than the second dielectric.
Aspect 21: The apparatus of any of aspects 8 through 20, where the second dielectric includes silicon oxycarbide.

An apparatus is described. The following provides an overview of aspects of the apparatus as described herein:
Aspect 22: An apparatus formed by a process including: forming a semiconductor material extending along a first direction over a substrate; forming a first dielectric material around a first portion of the semiconductor material; forming a gate of a cell selection transistor of a memory cell around a second portion of the semiconductor material, the gate including a first conductive material; forming a first material around an end of the semiconductor material along the first direction and in contact with the first dielectric material; forming a cavity based at least in part on removing a portion of the first material, the cavity exposing a third portion of the semiconductor material and exposing a sidewall of the first dielectric material; forming a first electrode of a capacitor of the memory cell based at least in part on forming a second conductive material in the cavity, the second conductive material including a first portion over the semiconductor material, a second portion along the sidewall of the first material and around the first portion of the second conductive material, and a third portion coupling the first portion of the second conductive material with the second portion of the second conductive material; forming a second dielectric material over the first electrode and at least partially within the cavity; and forming a second electrode of the capacitor of the memory cell over the second dielectric material based at least in part on forming a third conductive material at least partially within the cavity.
Aspect 23: The apparatus of aspect 22, formed by the process further including: exposing a portion of the sidewall of the first dielectric material, a portion of the semiconductor material, and a portion of a nitride material over the semiconductor material based at least in part on removing a second material; and removing the exposed portion of the semiconductor material, where forming the first material is performed after removing the exposed portion of the semiconductor material.
Aspect 24: The apparatus of aspect 23, formed by the process further including: exposing a portion of the first dielectric material based at least in part on removing the portion of the nitride material, where forming the cavity exposes the portion of the first dielectric material.
Aspect 25: The apparatus of any of aspects 22 through 24, formed by the process further including: forming a nitride material in contact with the second conductive material and filling the cavity; and removing a portion of the second conductive material after removing the nitride material, where removing the portion of the second conductive material exposes a portion of the first material.
Aspect 26: The apparatus of any of aspects 22 through 25, formed by the process further including: exposing an end of the semiconductor material based at least in part on removing a portion of the second conductive material, where forming the second dielectric material is performed after exposing the end of the semiconductor material.

An apparatus is described. The following provides an overview of aspects of the apparatus as described herein:
Aspect 27: An apparatus, including a cell selection transistor of a memory cell, a channel of the cell selection transistor comprising a first portion of a semiconductor material extending along a first direction over a substrate; a capacitor of the memory cell coupled with the channel of the cell selection transistor and associated with an axis along the first direction, the capacitor comprising: a first portion of a first electrode of the capacitor around a second portion of the semiconductor material about the axis, wherein the first portion of the first electrode is noncontiguous over an end of the second portion of the semiconductor material, a first portion of a first dielectric of the capacitor around the first portion of the first electrode about the axis, a portion of a second electrode of the capacitor around the first portion of the first dielectric about the axis, a second portion of the first dielectric around the second electrode about the axis, and a second portion of the first electrode around the second portion of the first dielectric about the axis.
Aspect 28: The apparatus of aspect 27, further including a third portion of the first dielectric around the second portion of the first electrode about the axis; and a second portion of the second electrode around the third portion of the first dielectric about the axis.
Aspect 29, the apparatus of any of aspects 27 through 28, where the first portion of the first dielectric is contiguous with the second portion of the first dielectric over an end of the portion of the second electrode.
Aspect 30, the apparatus of any of aspects 27 through 29, where the first portion of the first dielectric is contiguous over an end of the second portion of the semiconductor material.
Aspect 31, the apparatus of any of aspects 27 through 30, where the portion of the second electrode is contiguous over an end of the second portion of the semiconductor material.
Aspect 32, the apparatus of any of aspects 27 through 31, further including: a second dielectric between the cell selection transistor and the capacitor along the first direction and around the semiconductor material between the first portion of the semiconductor material and the second portion of the semiconductor material.
Aspect 33, the apparatus of aspect 32, where the first portion of the first electrode is contiguous with the second portion of the first electrode via a third portion of the first electrode that is in contact with the second dielectric.
Aspect 34, the apparatus of aspect 33, further including: a fourth portion of the first dielectric contiguous with the third portion of the first dielectric and over and end of the second portion of the second electrode, the fourth portion of the first dielectric in contact with the second dielectric.
Aspect 35, the apparatus of any of aspects 33 through 34, where the second portion of the first dielectric is contiguous with the third portion of the first dielectric over an end of the second portion of the first electrode.
Aspect 36, the apparatus of any of aspects 32 through 35, further including: a third dielectric between a gate of the cell selection transistor and the channel, the third dielectric in contact with the second dielectric.
Aspect 37, the apparatus of aspect 36, where an interface between the second dielectric and the third dielectric comprises a grain boundary.
Aspect 38, the apparatus of any of aspects 32 through 37, further including: a fourth dielectric between a gate of the cell selection transistor and the second dielectric, wherein the fourth dielectric is in contact with the second dielectric.
Aspect 39, the apparatus of aspect 38, where the fourth dielectric comprises a nitride material that is different than the second dielectric.
Aspect 40, the apparatus of any of aspects 32 through 39, where the second dielectric comprises silicon oxycarbide.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of the memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all the one or more components. For example, referring to “the one or more components” subsequently in the claims may be understood to be equivalent to referring to “at least one of the one or more components.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a cell selection transistor of a memory cell, a channel of the cell selection transistor comprising a first portion of a semiconductor material extending along a first direction over a substrate;
a capacitor of the memory cell coupled with the channel of the cell selection transistor and associated with an axis along the first direction, the capacitor comprising:
a first portion of a first electrode of the capacitor around a second portion of the semiconductor material about the axis;
a first portion of a first dielectric of the capacitor around the first portion of the first electrode about the axis;
a portion of a second electrode of the capacitor around the first portion of the first dielectric about the axis;
a second portion of the first dielectric around the second electrode about the axis; and
a second portion of the first electrode around the second portion of the first dielectric about the axis; and
a second dielectric between the cell selection transistor and the capacitor along the first direction and around the semiconductor material between the first portion of the semiconductor material and the second portion of the semiconductor material.

2. The apparatus of claim 1, wherein the first portion of the first electrode is contiguous with the second portion of the first electrode via a third portion of the first electrode that is in contact with the second dielectric.

3. The apparatus of claim 2, further comprising:
a fourth portion of the first dielectric contiguous with the third portion of the first dielectric and over and end of the second portion of the second electrode, the fourth portion of the first dielectric in contact with the second dielectric.

4. The apparatus of claim 2, wherein the second portion of the first dielectric is contiguous with the third portion of the first dielectric over an end of the second portion of the first electrode.

5. The apparatus of claim 1, further comprising:
a third portion of the first dielectric around the second portion of the first electrode about the axis; and
a second portion of the second electrode around the third portion of the first dielectric about the axis.

6. The apparatus of claim 1, wherein the first portion of the first dielectric is contiguous with the second portion of the first dielectric over an end of the portion of the second electrode.

7. The apparatus of claim 1, wherein the first portion of the first dielectric is contiguous over an end of the second portion of the semiconductor material.

8. The apparatus of claim 1, wherein the portion of the second electrode is contiguous over an end of the second portion of the semiconductor material.

9. The apparatus of claim 1, wherein the first portion of the first electrode is noncontiguous over an end of the second portion of the semiconductor material.

10. The apparatus of claim 1, further comprising:
a third dielectric between a gate of the cell selection transistor and the channel, the third dielectric in contact with the second dielectric.

11. The apparatus of claim 10, wherein an interface between the second dielectric and the third dielectric comprises a grain boundary.

12. The apparatus of claim 1, further comprising:
a fourth dielectric between a gate of the cell selection transistor and the second dielectric, wherein the fourth dielectric is in contact with the second dielectric.

13. The apparatus of claim 12, wherein the fourth dielectric comprises a nitride material that is different than the second dielectric.

14. The apparatus of claim 1, wherein the second dielectric comprises silicon oxycarbide.

15. A method, comprising:
forming a semiconductor material extending along a first direction over a substrate;
forming a first dielectric material around a first portion of the semiconductor material;
forming a gate of a cell selection transistor of a memory cell around a second portion of the semiconductor material, the gate comprising a first conductive material;
forming a first material around an end of the semiconductor material along the first direction and in contact with the first dielectric material;
forming a cavity based at least in part on removing a portion of the first material, the cavity exposing a third portion of the semiconductor material and exposing a sidewall of the first dielectric material;
forming a first electrode of a capacitor of the memory cell based at least in part on forming a second conductive material in the cavity, the second conductive material comprising a first portion over the third portion of the semiconductor material, a second portion along the sidewall of the first material and around the first portion of the second conductive material, and a third portion coupling the first portion of the second conductive material with the second portion of the second conductive material;
forming a second dielectric material over the first electrode and at least partially within the cavity; and
forming a second electrode of the capacitor of the memory cell over the second dielectric material based at least in part on forming a third conductive material at least partially within the cavity.

16. The method of claim 15, further comprising:
exposing a portion of the sidewall of the first dielectric material, a portion of the semiconductor material, and a portion of a nitride material over the semiconductor material based at least in part on removing a second material; and
removing the exposed portion of the semiconductor material, wherein forming the first material is performed after removing the exposed portion of the semiconductor material.

17. The method of claim 16, further comprising:
exposing a portion of the first dielectric material based at least in part on removing the portion of the nitride material, wherein forming the cavity exposes the portion of the first dielectric material.

18. The method of claim 15, further comprising:
forming a nitride material in contact with the second conductive material and filling the cavity; and
removing a portion of the second conductive material after removing the nitride material, wherein removing the portion of the second conductive material exposes a portion of the first material.

19. The method of claim 18, further comprising:
removing the nitride material from the cavity, wherein forming the second dielectric material is performed after removing the nitride material.

20. An apparatus, comprising:
a cell selection transistor of a memory cell, a channel of the cell selection transistor comprising a first portion of a semiconductor material extending along a first direction over a substrate;
a capacitor of the memory cell coupled with the channel of the cell selection transistor and associated with an axis along the first direction, the capacitor comprising:
a first portion of a first electrode of the capacitor around a second portion of the semiconductor material about the axis, wherein the first portion of the first electrode is noncontiguous over an end of the second portion of the semiconductor material;
a first portion of a first dielectric of the capacitor around the first portion of the first electrode about the axis;
a portion of a second electrode of the capacitor around the first portion of the first dielectric about the axis;
a second portion of the first dielectric around the second electrode about the axis; and
a second portion of the first electrode around the second portion of the first dielectric about the axis.

21. The apparatus of claim 20, further comprising:
a third portion of the first dielectric around the second portion of the first electrode about the axis; and
a second portion of the second electrode around the third portion of the first dielectric about the axis.

22. The apparatus of claim 20, wherein the first portion of the first dielectric is contiguous with the second portion of the first dielectric over an end of the portion of the second electrode.

23. The apparatus of claim 20, wherein the first portion of the first dielectric is contiguous over an end of the second portion of the semiconductor material.

24. The apparatus of claim 20, wherein the portion of the second electrode is contiguous over an end of the second portion of the semiconductor material.

25. The apparatus of claim 20, further comprising:
a second dielectric between the cell selection transistor and the capacitor along the first direction and around the semiconductor material between the first portion of the semiconductor material and the second portion of the semiconductor material.
